(19) United States
(12) Patent Application Publication
(10) Pub. No.: US 2025/0063903 A1
(43) Pub. Date: Feb. 20, 2025

(54) DISPLAY DEVICE

(71) Applicant: Samsung Display Co., LTD., Yongin-si (KR)

(72) Inventors: Young Gu KANG, Yongin-si (KR); Hyeon Do PARK, Yongin-si (KR); Sung Chan JO, Yongin-si (KR); Hyun Sung PARK, Yongin-si (KR); Yu Deok SEO, Yongin-si (KR)

(21) Appl. No.: 18/634,784

(22) Filed: Apr. 12, 2024

(30) Foreign Application Priority Data
Aug. 14, 2023 (KR) 10-2023-0106151

(51) Int. Cl. H10K 59/131; G09G 3/3266; H01L 27/02

(52) U.S. Cl. CPC H10K 59/131; G09G 3/3266; H01L 27/0255; G09G 2330/06

(57) ABSTRACT

A display device according to one or more embodiments includes a display device including a substrate including a display area and a non-display area, pixels in the display area above the substrate, an electrostatic discharge circuit in the non-display area above the substrate, a first line in the non-display area above the substrate, and configured to receive a first voltage, a second line in the non-display area above the substrate, and configured to receive a second voltage that is lower than the first voltage, a first connection line connected between the first line and the electrostatic discharge circuit under the first line on the substrate, and a second connection line connected between the second line and the electrostatic discharge circuit under the second line on the substrate.

### CROSS-REFERENCE TO RELATED APPLICATION

The present application claims priority to and the benefit of Korean Patent Application No. 10-2023-0106151, filed on Aug. 14, 2023, in the Korean Intellectual Property Office, the entire disclosure of which is incorporated herein by reference.

### BACKGROUND

### 1. Field

The present disclosure relates to a display device.

### 2. Description of the Related Art

The importance of display devices has steadily increased with the development of multimedia technology. A display device may include pixels arranged in a display area and signal lines connected to the pixels. Static electricity may be introduced into the display device through the signal lines, which may cause damage to the display device. In order to reduce or prevent damage due to static electricity, the display device may include an electrostatic discharge (ESD) circuit for quickly discharging static electricity.

### SUMMARY

Aspects of the present disclosure provide a display device including an electrostatic discharge circuit and capable of reducing or preventing damage to the electrostatic discharge circuit that may occur during a manufacturing process.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including a substrate including a display area and a non-display area, pixels in the display area above the substrate, an electrostatic discharge circuit in the non-display area above the substrate, a first line in the non-display area above the substrate, and configured to receive a first voltage, a second line in the non-display area above the substrate, and configured to receive a second voltage that is lower than the first voltage, a first connection line connected between the first line and the electrostatic discharge circuit under the first line on the substrate, and a second connection line connected between the second line and the electrostatic discharge circuit under the second line on the substrate.

The first line and the second line may be spaced from each other with the electrostatic discharge circuit therebetween, wherein the electrostatic discharge circuit is spaced from the first line and the second line by a same distance.

The display device may further include data lines extending from the non-display area to the display area, and connected to the pixels, wherein first ends of the data lines are connected to the electrostatic discharge circuit.

The electrostatic discharge circuit may include diode units respectively connected to the data lines, the diode units including a first diode connected between the first connection line and the one of the data lines, and spaced from the first line by a first distance, and a second diode connected between the second connection line and the one of the data lines, and spaced from the second line by a second distance.

The first distance and the second distance may be substantially equal to each other.

The first diode may include a first transistor diode-connected between the first connection line and the one of the data lines, wherein the second diode includes a second transistor diode-connected between the one of the data lines and the second connection line.

The diode units may include a first transistor and a second transistor, the first transistor and the second transistor including an active layer above the substrate, a gate electrode above an insulating layer covering the active layer, and a source electrode and a drain electrode above another insulating layer covering the gate electrode and spaced apart from each other.

The display device may further include conductive patterns overlapping a separation space between the source electrode and the drain electrode, beneath the source electrode and the drain electrode.

The conductive patterns may cover the active layer in a separation space between the source electrode and the drain electrode.

The conductive patterns may overlap the gate electrode, the source electrode, and the drain electrode.

The gate electrode may be provided in a first gate conductive layer above the active layer, wherein the conductive patterns may be provided in a second gate conductive layer above an insulating layer covering the first gate conductive layer, or provided in a third gate conductive layer above an insulating layer covering the second gate conductive layer.

The display device may further include a circuit layer above the substrate, and provided with the first transistor and the second transistor, the first line, the second line, the first connection line, and the second connection line, the circuit layer including a semiconductor layer above the substrate, and including the active layer, a first gate conductive layer above an insulating layer covering the semiconductor layer, and including the gate electrode, a second gate conductive layer above an insulating layer covering the first gate conductive layer, and a source-drain conductive layer above an insulating layer covering the second gate conductive layer, and including the source electrode and the drain electrode.

The first line and the second line may be provided in the source-drain conductive layer.

The first connection line and the second connection line may be provided in the first gate conductive layer or the second gate conductive layer.

The circuit layer may further include a third gate conductive layer above an insulating layer covering the second gate conductive layer, wherein the first connection line and the second connection line may be provided in the third gate conductive layer.

The display device may further include a gate-driving circuit in the non-display area on the substrate, and connected to the first line, the second line, and the pixels.

The first line and the second line may include a first line portion connected to the electrostatic discharge circuit, and a second line portion connected to the gate-driving circuit, and spaced apart from the first line portion, wherein the display device further includes a first bridge line connecting the first line portion and the second line portion of the first line beneath the first line on the substrate, and a second bridge line connecting the first line portion and the second line portion of the second line beneath the second line on the substrate.

The first line may be configured to transmit a gate high voltage to the gate-driving circuit, wherein the second line is configured to transmit a gate low voltage to the gate-driving circuit.

According to an aspect of the present disclosure, there is provided a display device including pixels in a display area, data lines connected to the pixels, an electrostatic discharge circuit at a side of the display area, and connected to the data lines, a gate-driving circuit at another side of the display area, and connected to the pixels, a first line for transmitting a first voltage to the gate-driving circuit, and including a first line portion connected to the electrostatic discharge circuit, and a second line portion spaced apart from the first line portion and connected to the gate-driving circuit, a second line for transmitting a second voltage to the gate-driving circuit, and including a first line portion connected to the electrostatic discharge circuit, and a second line portion spaced from the first line portion and connected to the gate-driving circuit, a first bridge line connected between the first line portion and the second line portion of the first line beneath the first line, and a second bridge line connected between the first line portion and the second line portion of the second line beneath the second line.

The display device may further include a first connection line connected between the first line and the electrostatic discharge circuit beneath the first line, and
a second connection line connected between the second line and the electrostatic discharge circuit beneath the second line.

A display device according to one or more embodiments may include an electrostatic discharge circuit to reduce or prevent damage due to static electricity. In some embodiments, the electrostatic discharge circuit may be connected to a first line and a second line to which a first voltage and a second voltage are applied via connection lines located under the first line and the second line. Therefore, it is possible to reduce or prevent damage to the display device due to static electricity introduced while the manufactured display device is being used, and also possible to reduce or prevent damage to the electrostatic discharge circuit due to static electricity that may be introduced during the manufacturing process of the display device. Accordingly, the defect rate of the display device may be reduced, and the yield may be increased.

In some embodiments, the electrostatic discharge circuit may include a conductive pattern disposed to overlap a separation space between a source electrode and a drain electrode of a transistor constituting each diode. Accordingly, damage to the electrostatic discharge circuit due to static electricity may be reduced or prevented more effectively.

In some embodiments, the first line and the second line may not be formed as a continuous line in the same conductive layer around the electrostatic discharge circuit, and may be physically disconnected. The disconnected line portions of the first line and the second line may be electrically connected to each other through the connection line thereunder. Accordingly, it is possible to effectively reduce or prevent damage to the display device due to static electricity that may be introduced through an upper conductive layer during the manufacturing process and the usage of the display device.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a perspective view illustrating a display device according to one or more embodiments;

FIG. 2 is a plan view illustrating the display device of FIG. 1;

FIG. 3 is a plan view illustrating a display panel according to one or more embodiments;

FIG. 4 is a circuit diagram illustrating a pixel according to one or more embodiments;

FIG. 5 is a cross-sectional view illustrating the display panel according to one or more embodiments;

FIG. 6 is a plan view schematically showing a first electrostatic discharge circuit according to one or more embodiments;

FIG. 7 is a circuit diagram showing a diode unit according to one or more embodiments;

FIG. 8 is a circuit diagram showing the diode unit according to one or more embodiments;

FIG. 9 is a circuit diagram showing the diode unit according to one or more embodiments;

FIG. 10 is a plan view showing the diode unit according to one or more embodiments;

FIG. 11 is a cross-sectional view showing the diode unit according to one or more embodiments;

FIG. 12 is a cross-sectional view showing the diode unit according to one or more embodiments;

FIG. 13 is a cross-sectional view showing the diode unit according to one or more embodiments;

FIG. 14 is a plan view showing the diode unit according to one or more embodiments;

FIG. 15 is an enlarged plan view showing area C of FIG. 14;

FIG. 16 is a cross-sectional view showing the diode unit according to one or more embodiments;

FIG. 17 is a cross-sectional view showing the diode unit according to one or more embodiments;

FIG. 18 is simulation data showing the intensity of the electric field applied to each channel of the first electrostatic discharge circuit according to one or more embodiments; and

FIG. 19 is a plan view showing area A of FIG. 3.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

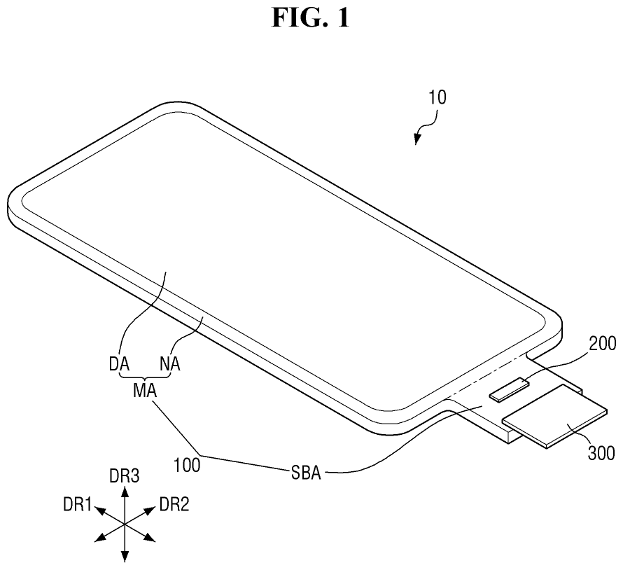

FIG. 1 is a perspective view illustrating a display device 10 according to one or more embodiments.

Referring to FIG. 1, a display device 10 is a device for displaying a moving image or a still image. The display device 10 may be used as a display screen of various devices, such as a television, a laptop computer, a monitor, a billboard and an Internet-of-Things (IOT) device, as well as portable electronic devices, such as a mobile phone, a smartphone, a tablet personal computer (PC), a smart watch, a watch phone, a mobile communication terminal, an electronic notebook, an electronic book, a portable multimedia player (PMP), a navigation device, and an ultra-mobile PC (UMPC).

In one or more embodiments, the display device 10 may be a light-emitting display device, such as an organic light-emitting display including an organic light-emitting diode, a quantum dot light-emitting display including a quantum dot light-emitting layer, an inorganic light-emitting display including an inorganic semiconductor, or a micro light-emitting display including a micro or nano light-emitting diode (LED). The display device 10 may be another type of display device other than a light-emitting display device. In the present disclosure, various embodiments in which the display device 10 is an organic light-emitting display device are described, but the type of display device 10 according to the embodiments is not limited thereto.

In one or more embodiments, the display device 10 may be formed flat. For example, the display device 10 may be formed substantially flat on a plane defined by a first direction DR1 and a second direction DR2, and may have a thickness (or height) in a third direction DR3. In one or more other embodiments, the display device 10 may include a curved surface in at least a part including an edge region and the like. In addition, the display device 10 may be formed flexibly so that it can be curved, bent, folded, or rolled.

In one or more embodiments, with respect to the image display surface of the display device 10, the first direction DR1 may be a lengthwise direction, a column direction, or a vertical direction of the display device 10, and the second direction DR2 may be a direction crossing the first direction DR1, for example, a widthwise direction, a row direction, or a horizontal direction of the display device 10. The third direction DR3 is a direction crossing the first direction DR1 and the second direction DR2 and may be, for example, a thickness direction or a height direction of the display device 10.

The display device 10 may include a display panel 100, a driving circuit 200, and a circuit board 300.

The display panel 100 may include a main region MA including a display area DA in which an image is displayed, and a sub-region SBA located on one side of the main region MA.

The main region MA may include the display area DA, and a non-display area NA surrounding the display area DA (e.g., in plan view). The non-display area NA may be positioned at an edge of the main region MA and may be in contact with the sub-region SBA.

In one or more embodiments, the main region MA may include a long side in the first direction DR1, and a short side in the second direction DR2, and may be formed as a plane having an approximately rectangular shape. A corner portion at which the long side and the short side of the main region MA meet may be rounded, right-angled, or the like. The shape of the main region MA may be variously changed according to one or more embodiments. For example, the main region MA may be formed in a polygonal shape other than a quadrilateral shape, a circular shape, an elliptical shape, or the like.

The display area DA may be an area in which pixels are arranged, and may be an area in which an image is displayed by pixels. The display area DA may be positioned in the center of the main region MA, and may occupy most of the area in the main region MA. In one or more embodiments, sensing patterns (for example, touch electrodes) for sensing a touch input or the like may be further provided in the display area DA.

In one or more embodiments, the display area DA may have a shape corresponding to the shape of the main region MA. For example, the display area DA may include a long side in the first direction DR1 and a short side in the second direction DR2, and may be formed as a plane having an approximately rectangular shape. A corner portion at which the long side and the short side of the display area DA meet may be rounded, right-angled, or the like. The shape of the display area DA in a plan view is not limited to a rectangular shape, but may be formed in another polygonal shape, a circular shape, an elliptical shape, or the like.

The non-display area NA may be positioned right around the display area DA. For example, the non-display area NA may be located at the edge of the main region MA, and may surround the display area DA (e.g., in plan view). The non-display area NA may be in contact with the sub-region SBA.

Wires (or parts of wires) connected to pixels may be located in the non-display area NA. In one or more embodiments, a gate-driving circuit (for example, an embedded circuit including a scan-driving circuit for generating scan signals of pixels and/or an emission control circuit for generating emission control signals of pixels) may be further located in the non-display area NA. For example, the gate-driving circuit may be located in the non-display area NA located on (or located at or around) at least one side of the display area DA.

The sub-region SBA may be located on one side of the main region MA. For example, the sub-region SBA may protrude in the first direction DR1 from one side of the main region MA. For example, the sub-region SBA may protrude in the first direction DR1 from the lower end of the main region MA.

In one or more embodiments, the sub-region SBA may have a narrower width than the main region MA. For example, with respect to the second direction DR2, the sub-region SBA may have a narrower width than the main region MA.

Wires (or parts of wires) and pads may be provided in the sub-region SBA. For example, in the sub-region SBA, the wires and pads connected to the pixels and/or the gate-driving circuit positioned in the main region MA and to the driving circuit 200 and/or the circuit board 300 positioned in the sub-region SBA may be located. In describing embodiments, the term “connect” may include electrical connection and/or physical connection.

In one or more embodiments, the driving circuit 200 (e.g., the display driving circuit) may be mounted in the sub-region SBA. The circuit board 300 may be located on a portion of the sub-region SBA.

The driving circuit 200 may be connected to pixels PX of the display area DA. The driving circuit 200 may include a data driving circuit to drive pixels. The driving circuit 200 may supply driving signals (for example, data signals of the pixels PX) to the pixels PX.

In one or more embodiments, the driving circuit 200 may be implemented as an integrated circuit chip (IC) and mounted in the sub-region SBA. In one or more other embodiments, the driving circuit 200 may be provided or mounted on the circuit board 300 on the sub-region SBA, or may be provided or mounted on another circuit board connected to the display panel 100 through the circuit board 300.

In one or more embodiments, the driving circuit 200 may further include a timing control circuit for controlling the gate-driving circuit and the data driving circuit. In one or more other embodiments, the timing control circuit may be provided or mounted on the circuit board 300 connected to the display panel 100 through pads provided on the display panel 100, or may be provided or mounted on another circuit board connected to the circuit board 300.

The circuit board 300 may be located on a part of the sub-region SBA. For example, the circuit board 300 may be bonded on the pads positioned on a portion (e.g., a lower edge) of the sub-region SBA, and may supply or transmit power voltages and driving signals for driving the display panel 100 to the display panel 100. For example, the circuit board 300 may supply input image data (e.g., digital image data), driving signals including timing signals, and driving voltages to the display panel 100. The circuit board 300 may be a flexible film, such as a flexible printed circuit board (FPCB), a printed circuit board (PCB), or a chip on film (COF), but is not limited thereto.

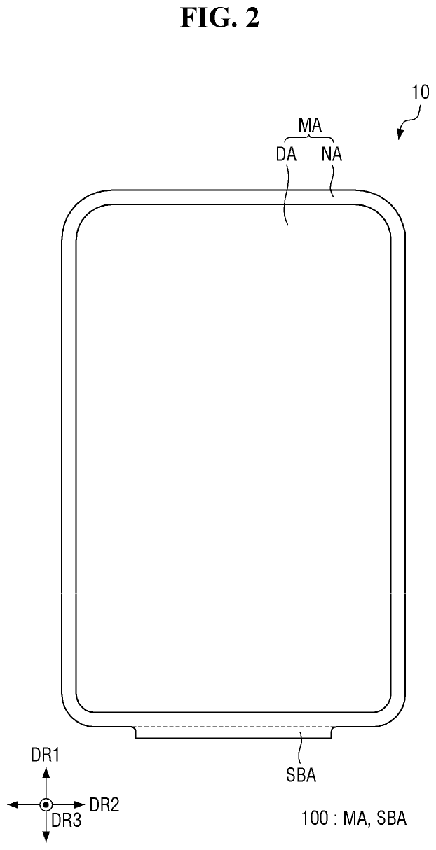

FIG. 2 is a plan view illustrating the display device 10 of FIG. 1. FIG. 1 shows the display device 10 unfolded without bending, and FIG. 2 shows the display device 10 bent in the sub-region SBA. For example, FIG. 1 illustrates a state in which the sub-region SBA is spread out parallel to the main region MA, and FIG. 2 illustrates a state in which the sub-region SBA is bent such that a part of the sub-region SBA is positioned below the main region MA.

Referring to FIG. 2 in addition to FIG. 1, the sub-region SBA may be formed flexibly so that at least a part of the sub-region SBA can be curved, bent, folded, or rolled. In one or more embodiments, the sub-region SBA may be bent at a portion adjacent to the non-display area NA. Accordingly, a portion of the sub-region SBA in which the driving circuit 200 is mounted may be positioned below the main region MA (e.g., with respect to a third direction DR3).

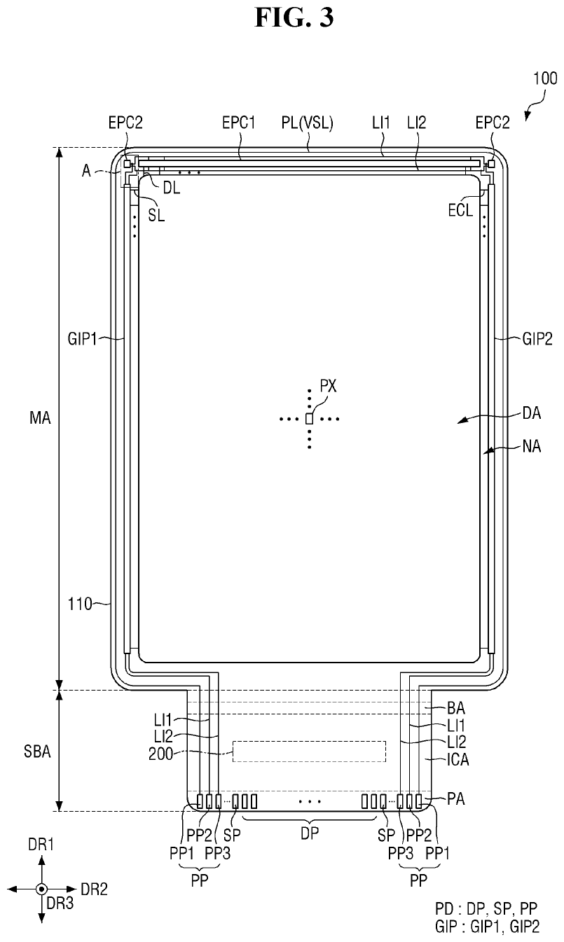

FIG. 3 is a plan view illustrating the display panel 100 according to one or more embodiments. FIG. 3 shows the display panel 100 in an unbent and unfolded state.

Referring to FIG. 3 in addition to FIGS. 1 and 2, the display panel 100 may include the main region MA including the display area DA and the non-display area NA, and the sub-region SBA including a pad area PA. In the display device 10 in which the driving circuit 200 is mounted on the sub-region SBA of the display panel 100, the sub-region SBA may further include a driving-circuit-mounting area ICA where the driving circuit 200 is mounted. In the display device 10 in which the display panel 100 is bent in the sub-region SBA of the display panel 100, the sub-region SBA may further include a bending area BA. In one or more embodiments, the bending area BA may be adjacent to the main region MA, and may be located between the main region MA and the driving-circuit-mounting area ICA.

The display panel 100 may include a substrate 110 (or base layer) forming a base surface. The substrate 110 may include the main region MA including the display area DA and the non-display area NA. In one or more embodiments, the substrate 110 may further include the sub-region SBA protruding from the main region MA.

The display panel 100 may include the pixels PX, a first electrostatic discharge circuit EPC1, and the pads PD located and/or formed on the substrate 110. In one or more embodiments, the display panel 100 may further include a gate-driving circuit GIP and/or a second electrostatic discharge circuit EPC2 located and/or formed on the substrate 110 (as used herein, “located on” or “formed on” may mean “located or formed above”). The display panel 100 may further include wires located and/or formed on the substrate 110. The wires may be connected to the pixels PX, the gate-driving circuit GIP, the first electrostatic discharge circuit EPC1, the second electrostatic discharge circuit EPC2, the driving circuit 200, and/or the pads PD.

The pixels PX may be located in the display area DA. Wires (or parts of wires) connected to the pixels PX may be further located in the display area DA. For example, scan lines SL, data lines DL, and pixel power lines PL (or a plurality of pixel power lines PL transmitting different pixel power voltages) connected to the pixels PX may be further located in the display area DA. In the display device 10 in which the emission timing of the pixels PX is controlled by the emission control signal, emission control lines ECL for transmitting the emission control signals to the pixels PX may be further located in the display area DA.

In one or more embodiments, at least one pixel power line PL connected to the pixels PX may be formed to surround the display area DA at the outer side of the display area DA. For example, a second pixel power line VSL transmitting the second pixel power voltage to the pixels PX may be formed to surround the display area DA in the non-display area NA. Although FIG. 3 shows only a part of the pixel power line PL located in the non-display area NA (for example, a part of the second pixel power line VSL), the pixel power line PL may extend into the display area DA to be connected to pixels PX. In one or more embodiments, the pixel power line PL may include a line portion provided or included in a conductive layer that is different from a conductive layer including a line portion surrounding the display area DA is provided at the periphery of the display area DA and/or in the display area DA. Further, although FIG. 3 shows only one pixel power line PL, the pixels PX may receive at least two pixel power voltages, and the display panel 100 may include at least two pixel power lines PL for transmitting pixel power voltages to the pixels PX.

The gate-driving circuit GIP may be located in the non-display area NA. The gate-driving circuit GIP may be connected to a first line LI1 and a second line LI2, and may receive voltages required to generate gate signals from the first line LI1 and the second line LI2. The gate-driving circuit GIP may be connected to the pixels PX through gate lines (for example, the scan lines SL and/or the emission control lines ECL), and may supply gate signals (for example, the scan signals and/or the emission control signals) to the pixels PX.

The gate-driving circuit GIP may be located on (or located at or around) at least one side of the display area DA. For example, the gate-driving circuit GIP may include a first gate-driving circuit GIP1 located on one side (for example, left side) of the display area DA, and may selectively further include a second gate-driving circuit GIP2 located on the other side (for example, right side) of the display area DA. In one or more embodiments, the first gate-driving circuit GIP1 may include the scan-driving circuit connected to the pixels PX through the scan lines SL, and the second gate-driving circuit GIP2 may include the emission control circuit connected to the pixels PX through the emission control lines ECL. The configuration and/or position of the gate-driving circuit GIP may be changed according to one or more embodiments.

In one or more embodiments, the gate-driving circuit GIP may be an embedded circuit provided and/or formed in the display panel 100 together with the pixels PX. For example, the gate-driving circuit GIP may be formed on the display panel 100 by a gate-in panel method.

The first electrostatic discharge circuit EPC1 may be located in the non-display area NA, and may be located on (or located at or around) one side of the display area DA. For example, the first electrostatic discharge circuit EPC1 may be located in a part of the non-display area NA located at the upper side of the display area DA.

The first electrostatic discharge circuit EPC1 may be connected to the first line LI1, the second line LI2, and the data lines DL. For example, the first electrostatic discharge circuit EPC1 may include diodes connected to the first line LI1, the second line LI2, and the data lines DL.

Although it is illustrated in FIG. 3 that only one end of each of the data lines DL is connected to the first electrostatic discharge circuit EPC1, the other end of each of the data lines DL may be connected to the driving circuit 200. For example, the data lines DL (or wires connected to the data lines DL) may extend from the driving-circuit-mounting area ICA of the sub-region SBA to the display area DA via the non-display area NA, and may be connected to the pixels PX in the display area DA. One end of each of the data lines DL may be connected to the first electrostatic discharge circuit EPC1.

In one or more embodiments, the diodes provided on the first electrostatic discharge circuit EPC1 may be formed of transistors diode-connected in a reverse direction between the first line LI1 and the second line LI2. The first electrostatic discharge circuit EPC1 may quickly discharge static electricity introduced into the display panel 100 through the first line LI1 or the second line LI2.

The second electrostatic discharge circuit EPC2 may be located in the non-display area NA, and may be located in the edge region of the display panel 100. For example, the second electrostatic discharge circuit EPC2 may be located in the upper left edge region and the upper right edge region of the display panel 100. The second electrostatic discharge circuit EPC2 may be connected to the first line LI1 and the second line LI2. For example, the second electrostatic discharge circuit EPC2 may include diodes connected to the first line LI1 and the second line LI2. The second electrostatic discharge circuit EPC2 may absorb or reduce electric shock caused by static electricity introduced into the display panel 100.

The pads PD may be located in the pad area PA. The pads PD may connect the display panel 100 and/or the driving circuit 200 to the circuit board 300 or the like. The circuit board 300 may be located or bonded on the pad area PA.

The pads PD may include power pads PP, signal pads SP, and data pads DP. The power pads PP may include at least one first power pad PP1 (for example, first power pads PP1 connected to both ends of the second pixel power line VSL) connected to each pixel power line PL, at least one second power pad PP2 (for example, second power pads PP2 connected to both ends of the first line LI1) connected to the first line LI1, at least one third power pad PP3 (for example, third power pads PP3 connected to both ends of the second line LI2) connected to the second line LI2, the signal pads SP connected to the gate-driving circuit GIP and/or the driving circuit 200, and the data pads DP connected to the driving circuit 200.

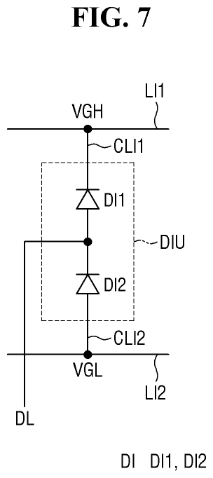

Each pixel power voltage may be applied to the first power pad PP1. A first voltage used for generating gate signals may be applied to the second power pad PP2. A second voltage used for generating gate signals may be applied to the third power pad PP3. The first voltage and the second voltage may be voltages of different levels. For example, the first voltage may be a gate high voltage (for example, a gate high voltage VGH applied to the first line LI1 of FIG. 7), and the second voltage may be a gate low voltage (for example, a gate low voltage VGL applied to the second line LI2 of FIG. 7), which is lower than the first voltage. Driving signals for controlling the operation of the gate-driving circuit GIP and/or the driving circuit 200 may be applied to the signal pads SP. Image data used for generating data signals may be supplied to the data pads DP. The type, position, arrangement order, and/or number of the pads PD provided in the pad area PA may be variously changed according to one or more embodiments.

The first line LI1 may be located in the non-display area NA. The first line LI1 may be connected between at least one second power pad PP2 and the gate-driving circuit GIP. The first line LI1 may transmit the first voltage (for example, the gate high voltage) applied through the second power pad PP2 to the gate-driving circuit GIP.

The first line LI1 may be further connected to the first electrostatic discharge circuit EPC1 and the second electrostatic discharge circuit EPC2. The first line LI1 may be utilized as a discharge path for discharging static electricity introduced from the outside.

The second line LI2 may be located in the non-display area NA. The second line LI2 may be connected between at least one third power pad PP3 and the gate-driving circuit GIP. The second line LI2 may transmit the second voltage (for example, the gate low voltage) applied through the third power pad PP3 to the gate-driving circuit GIP.

The second line LI2 may be further connected to the first electrostatic discharge circuit EPC1 and the second electrostatic discharge circuit EPC2. The second line LI2 may be utilized as a discharge path for discharging static electricity introduced from the outside.

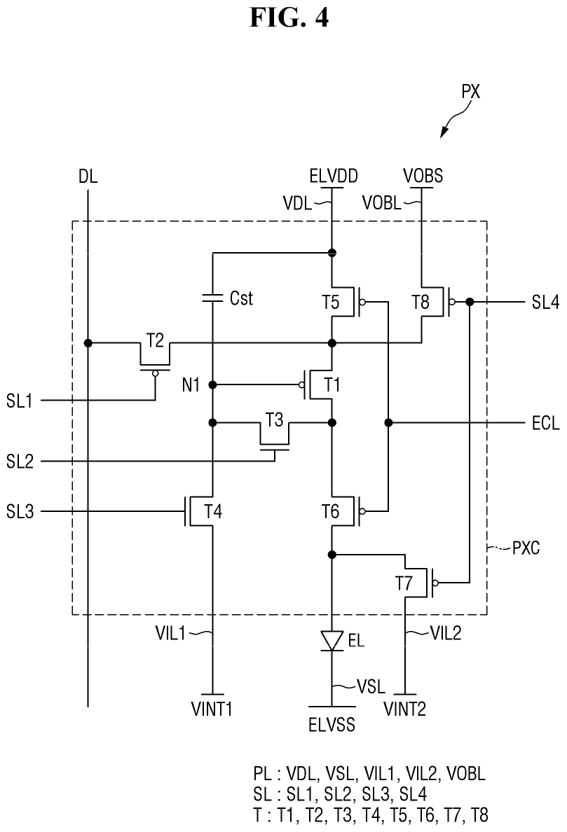

FIG. 4 is a circuit diagram illustrating the pixel PX according to one or more embodiments.

FIG. 4 illustrates one or more embodiments in which a pixel circuit PXC provided in the pixel PX includes first to eighth transistors T1 to T8. In one or more embodiments, scan lines SL connected to the pixel PX may include a first scan line SL1, a second scan line SL2, a third scan line SL3, and a fourth scan line SL4, and pixel power lines PL connected to the pixel PX may include a pixel power line VDL, a second pixel power line VSL, a first initialization power line VIL1, a second initialization power line VIL2, and a bias power line VOBL. The pixel PX may be further connected to the data line DL and the emission control line ECL. The configuration of the pixel circuit PXC and the type and number of wires connected to the pixel circuit PXC may be variously changed according to one or more embodiments.

Referring to FIG. 4 in addition to FIGS. 1 to 3, each of the pixels PX may include the pixel circuit PXC and a light-emitting element EL connected to the pixel circuit PXC. For example, each pixel PX may include the pixel circuit PXC and the light-emitting element EL connected to the pixel circuit PXC.

The pixel circuit PXC may control the light-emitting timing and luminance of the light-emitting element EL by controlling the driving current supplied to the light-emitting element EL. For example, the pixel circuit PXC may include pixel transistors T and a capacitor Cst that control the driving current in response to at least one scan signal and at least one data signal supplied to the corresponding pixel PX. In one or more embodiments, the pixel transistors T may include first to eighth transistors T1 to T8.

The first transistor T1 may include a gate electrode connected to a first node N1, a first electrode connected to the pixel power line VDL via the fifth transistor T5, and a second electrode connected to the light-emitting element EL via the sixth transistor T6. One of the first electrode and the second electrode may be a source electrode, and the other one may be a drain electrode. The first transistor T1 may control the driving current (e.g., the source-drain current of the first transistor T1) flowing between the first electrode and the second electrode according to the voltage applied to the gate electrode (e.g., according to the voltage of the first node N1 corresponding to the voltage of the data signal).

The second transistor T2 may include a gate electrode connected to the first scan line SL1, a first electrode connected to the data line DL, and a second electrode connected to the first electrode of the first transistor T1. The second transistor T2 may be turned on by the first scan signal supplied to the first scan line SL1 to connect the first electrode of the first transistor T1 to the data line DL. When the second transistor T2 is turned on, the voltage of the data signal supplied to the data line DL may be applied to the first electrode of the first transistor T1.

The third transistor T3 may include a gate electrode connected to the second scan line SL2, a first electrode connected to the second electrode of the first transistor T1, and a second electrode connected to a gate electrode (or the first node N1) of the first transistor T1. The third transistor T3 may be turned on by the second scan signal supplied to the second scan line SL2 to connect the gate electrode of the first transistor T1 to the second electrode of the first transistor T1. When the third transistor T3 is turned on, the first transistor T1 may be driven as a diode.

The fourth transistor T4 may include a gate electrode connected to the third scan line SL3, a first electrode connected to the gate electrode of the first transistor T1, and a second electrode connected to the first initialization power line VIL1. The fourth transistor T4 may be turned on by the third scan signal supplied to the third scan line SL3 to connect the gate electrode of the first transistor T1 to the first initialization power line VIL1. When the fourth transistor T4 is turned on, a first initialization voltage VINT1 (e.g., the gate initialization voltage) of the first initialization power line VIL1 may be applied to the gate electrode of the first transistor T1.

The fifth transistor T5 may include a gate electrode connected to the emission control line ECL, a first electrode connected to the pixel power line VDL, and a second electrode connected to the first electrode of the first transistor T1. The fifth transistor T5 may be turned on by the emission control signal supplied to the emission control line ECL, and thus may connect the first electrode of the first transistor T1 to the first pixel power line VDL to which a first pixel power voltage ELVDD is applied. When the fifth transistor T5 is turned on, the first pixel power voltage ELVDD may be applied to the first electrode of the first transistor T1. In one or more embodiments, the first pixel power voltage ELVDD may be a high potential pixel driving voltage.

The sixth transistor T6 may include the gate electrode connected to the emission control line ECL, the first electrode connected to the second electrode of the first transistor T1, and the second electrode connected to the light-emitting element EL. The sixth transistor T6 may be turned on by the emission control signal supplied to the emission control line EML to connect the first transistor T1 to the light-emitting element EL. When the fifth transistor T5 and the sixth transistor T6 are turned on, the driving current having a magnitude corresponding to the voltage of the gate electrode of the first transistor T1 may flow through the light-emitting element EL.

The seventh transistor T7 may include a gate electrode connected to the fourth scan line SL4, a first electrode (e.g., an anode electrode) connected to the first electrode of the light-emitting element EL, and a second electrode connected to the second initialization power line VIL2. The seventh transistor T7 may be turned on by the fourth scan signal supplied to the fourth scan line SL4 to connect the first electrode of the light-emitting element EL to the second initialization power line VIL2. The fourth scan signal may be the same signal as or a different signal from the first scan signal. When the seventh transistor T7 is turned on, a second initialization voltage VINT2 (e.g., an anode initialization voltage) of the second initialization power line VIL2 may be applied to the first electrode of the light-emitting element EL.

The eighth transistor T8 may include a gate electrode connected to the fourth scan line SL4, a first electrode connected to the bias power line VOBL, and a second electrode connected to the first electrode of the first transistor T1. The eighth transistor T8 may be turned on by the fourth scan signal supplied to the fourth scan line SL4 to connect the first electrode of the first transistor T1 to the bias power line VOBL. When the eighth transistor T8 is turned on, the bias voltage VOBS supplied to the bias power line VOBL may be applied to the first electrode of the first transistor T1. In one or more embodiments, the bias voltage VOBS may have a voltage level suitable for compensating for the hysteresis characteristic of the first transistor T1. As the eighth transistor T8 is turned on, the first electrode of the first transistor T1 may be initialized to the bias voltage VOBS.

The capacitor Cst may be connected between the gate electrode of the first transistor T1 (or the first node N1) and the first pixel power line VDL. The capacitor Cst may be charged with a voltage corresponding to the voltage of the data signal applied to the gate electrode of the first transistor T1.

The active layer (e.g., a semiconductor pattern including a channel region) of each of the pixel transistors T (e.g., the first to eighth transistors T1 to T8) may include one semiconductor material of polysilicon, amorphous silicon, or an oxide semiconductor. In one or more embodiments, some of the pixel transistors T and some others thereof may be formed of transistors of different conductivity types. In addition, some of the pixel transistors T and some others thereof may include different types of semiconductor materials.

For example, the first, second, fifth, sixth, seventh, and eighth transistors T1, T2, T5, T6, T7, and T8 may be formed of P-type transistors (e.g., P-type MOSFETs) including the respective active layers formed of polysilicon, and the third and fourth transistors T3 and T4 may be formed of N-type transistors (e.g., N-type MOSFETs) including the respective active layers formed of an oxide semiconductor. In one or more embodiments, the active layers formed of polysilicon and the active layers formed of an oxide semiconductor may be located in different layers on the substrate 110 of the display panel 100.

The light-emitting element EL may be connected between the pixel circuit PXC and the second pixel power line VSL. A second pixel power voltage ELVSS may be applied to the second pixel power line VSL. In one or more embodiments, the second pixel power voltage ELVSS may be a low potential pixel driving voltage. A potential difference between the first pixel power voltage ELVDD and the second pixel power voltage ELVSS may be greater than or equal to the threshold voltage of the light-emitting element EL. The light-emitting element EL may emit light corresponding to the driving current supplied from the pixel circuit PXC.

In one or more embodiments, the pixel PX may include a single light-emitting element EL, but is not limited thereto. For example, the pixel PX may include at least two light-emitting elements EL.

The light-emitting element EL may be an organic light-emitting diode, but is not limited thereto. For example, the light-emitting element EL may be an inorganic light-emitting element, a quantum dot light-emitting element, or another type of light-emitting element.

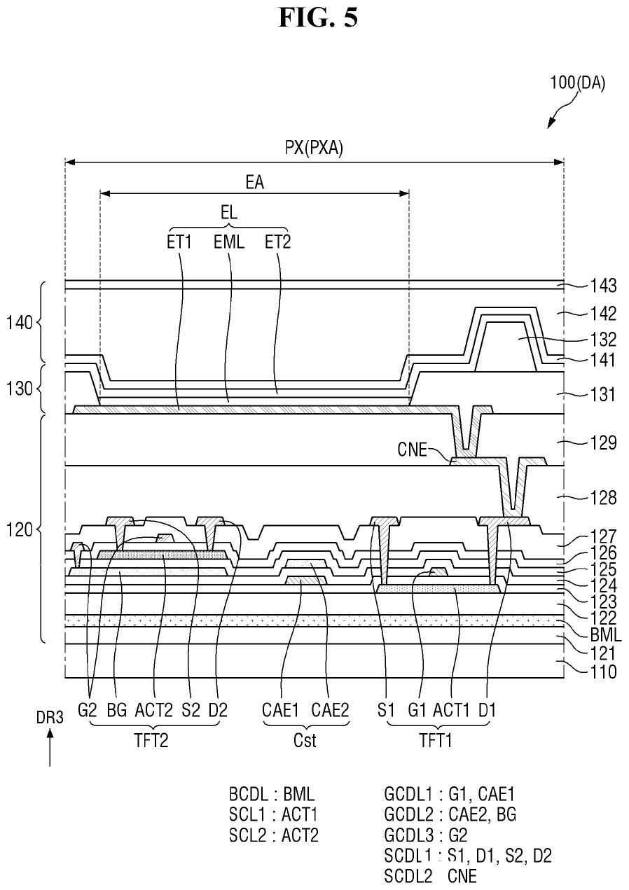

FIG. 5 is a cross-sectional view illustrating the display panel 100 according to one or more embodiments. For example, FIG. 5 schematically illustrates a cross section of a part of the display area DA corresponding to a pixel area PXA in which one pixel PX is positioned.

Referring to FIG. 5 in addition to FIGS. 1 to 4, the display panel 100 may include the substrate 110, and a circuit layer 120, a light-emitting element layer 130, and an encapsulation layer 140 located on the substrate 110. In one or more embodiments, the circuit layer 120, the light-emitting element layer 130, and the encapsulation layer 140 may be sequentially arranged and/or stacked on the substrate 110 along the third direction DR3. In describing the embodiments, the circuit layer 120 and the light-emitting element layer 130 are separately described, but the embodiments are not limited thereto. For example, the circuit layer 120 and the light-emitting element layer 130 may be integrated.

The substrate 110 may be a base member for forming the display panel 100, and may include the main region MA including the display area DA and the non-display area NA, and the sub-region SBA positioned on one side of the main region MA. In one or more embodiments, the substrate 110 may be made of a material having a flexible characteristic capable of bending, folding, rolling, or the like. The substrate 110 may include an insulating material, such as a polymer resin. For example, the substrate 110 may be made of polyimide or another insulating material. The substrate 110 may be a flexible substrate that can be transformed, such as bending, folding, or rolling. In one or more other embodiments, the substrate 110 may be a substrate including an insulating material, such as glass or the like and having rigid characteristics, and may not be bent.

The circuit layer 120 may include the pixel circuits PXC and wires provided in the pixels PX. For example, the circuit layer 120 may include wires (for example, the pixel power lines PL) connected to the pixels PX and circuit elements (for example, the pixel transistors T and the capacitor Cst of FIG. 4) constituting the pixel circuit PXC of each of the pixels PX, the scan lines SL, the emission control line ECL, and the data lines DL. In one or more embodiments, the circuit layer 120 may further include the circuit elements constituting the gate-driving circuit GIP, the first electrostatic discharge circuit EPC1, and the second electrostatic discharge circuit EPC2, and wires (for example, the first line LI1 and the second line LI2 of FIG. 3) connected to the gate-driving circuit GIP, the first electrostatic discharge circuit EPC1, and the second electrostatic discharge circuit EPC2. In one or more embodiments, the circuit layer 120 may be formed entirely on one surface of the substrate 110, including the main region MA and the sub-region SBA.

Among elements that may be provided on the circuit layer 120, FIG. 5 will illustrate a first thin film transistor TFT1 (also referred to as a “first pixel transistor”) provided in the pixel area PXA of each of the pixels PX, a second thin film transistor TFT2 (also referred to as a “second pixel transistor”), and a capacitor Cst. In one or more embodiments, the first thin film transistor TFT1 may represent first type transistors (e.g., P-type transistors) including a first semiconductor material (e.g., polysilicon) among the pixel transistors T constituting each of the pixel circuits PXC. For example, the first thin film transistor TFT1 may be one of the first, second, fifth, sixth, seventh, and/or eighth transistors T1, T2, T5, T6, T7, and/or T8. In FIG. 5, one transistor (for example, the sixth transistor T6 of FIG. 4) connected to the light-emitting element EL through a connection electrode CNE among the first type transistors is illustrated as the first thin film transistor TFT1. In one or more embodiments, the second thin film transistor TFT2 may represent second type transistors (e.g., N-type transistors) including a second semiconductor material (e.g., oxide semiconductor) among the pixel transistors T. For example, the second thin film transistor TFT2 may be one of the third and fourth transistors T3 and T4.

Cross sections of the pixels PX may be variously changed according to each of the pixels PX and the type and/or structure of the display panel 100 including the pixel PX. For example, positions and order of formation of the first thin film transistor TFT1, the second thin film transistor TFT2, and the capacitor Cst may vary according to one or more embodiments.

The circuit layer 120 may include semiconductor layers for forming circuit elements, wires, or the like, conductive layers, and insulating layers located between and/or around the semiconductor layers and the conductive layers. For example, the circuit layer 120 may include a first semiconductor layer SCL1 (e.g., a polysilicon semiconductor layer), a first insulating layer 123 (e.g., a first gate-insulating layer), a first gate conductive layer GCDL1 (or a first conductive layer), a second insulating layer 124 (e.g., a second gate-insulating layer), a second gate conductive layer GCDL2 (or a second conductive layer), a third insulating layer 125 (e.g., a first interlayer insulating layer), a second semiconductor layer SCL2 (e.g., an oxide semiconductor layer), a fourth insulating layer 126 (e.g., a third gate-insulating layer), a third gate conductive layer GCDL3 (or a third conductive layer), a fifth insulating layer 127 (e.g., a second interlayer insulating layer), a first source-drain conductive layer SCDL1 (or a fourth conductive layer), and a sixth insulating layer 128 (e.g., a first via layer or a first planarization layer).

In one or more embodiments, the circuit layer 120 may omit the second semiconductor layer SCL2 or the like. For example, in the display panel 100 in which the pixels PX include the pixel transistors T of the same type, and the active layers of the pixel transistors T are formed on the same layer, the circuit layer 120 may omit the second semiconductor layer SCL2, the fourth insulating layer 126 (for example, the third gate-insulating layer), and/or the third gate conductive layer GCDL3 (or the third conductive layer).

In one or more embodiments, the circuit layer 120 may further include at least one conductive layer and at least one insulating layer located on the sixth insulating layer 128. For example, the circuit layer 120 may further include a second source-drain conductive layer SCDL2 (or a fifth conductive layer) and a seventh insulating layer 129 (for example, a second via layer or a second planarization layer) that are sequentially arranged on the sixth insulating layer 128.

In one or more embodiments, the circuit layer 120 may further include at least one conductive layer and at least one insulating layer between the substrate 110 and the first semiconductor layer SCL1. For example, the circuit layer 120 may further include a lower conductive layer BCDL between the substrate 110 and the first semiconductor layer SCL1, a barrier layer 121 between the substrate 110 and the lower conductive layer BCDL, and a buffer layer 122 between the lower conductive layer BCDL and the first semiconductor layer SCL1.

The barrier layer 121 may be located on the substrate 110. The barrier layer 121 may protect elements located on the circuit layer 120 and the light-emitting element layer 130 from moisture permeating through the substrate 110, which may be susceptible to moisture permeation. The barrier layer 121 may include at least one inorganic layer containing an inorganic insulating material (e.g., silicon nitride, silicon oxide, silicon oxynitride, titanium oxide, aluminum oxide, or another inorganic insulating material). The material of the barrier layer 121 may be variously changed according to one or more embodiments.

The lower conductive layer BCDL may be located on the barrier layer 121. The lower conductive layer BCDL may include a lower metal layer BML overlapping the active layer (e.g., a first active layer ACT1 and/or a second active layer ACT2) of the at least one pixel transistor T, and/or at least one wire (or a part of the at least one wire). Although FIG. 5 illustrates that the lower metal layer BML covers the entire width of the pixel area PXA, embodiments are not limited thereto. For example, the lower metal layer BML may be patterned in an appropriate size and/or shape as needed and positioned only in a part of the pixel area PXA. For example, the lower metal layer BML may be positioned only in a part of the pixel area PXA to be positioned below the first transistor T1 illustrated in FIG. 4. In one or more embodiments, the lower metal layer BML may also be utilized as a light-blocking pattern and/or a back-gate electrode of at least one pixel transistor T, or the like.

The buffer layer 122 may cover the lower conductive layer BCDL. The buffer layer 122 may include at least one inorganic layer containing an inorganic insulating material.

The first thin film transistor TFT1, the second thin film transistor TFT2, and the capacitor Cst may be located on one surface of the substrate 110 including the buffer layer 122.

The first thin film transistor TFT1 may include the first active layer ACT1 and a first gate electrode G1. In one or more embodiments, the first thin film transistor TFT1 may further include a first source electrode S1 and a first drain electrode D1 connected to the first active layer ACT1. In one or more other embodiments, the first thin film transistor TFT1 may omit a separate first source electrode S1 and/or a separate first drain electrode D1, and may include a source electrode and/or a drain electrode formed integrally with the source region and/or the drain region of the first active layer ACT1.

The second thin film transistor TFT2 may include the second active layer ACT2 and a second gate electrode G2. In one or more embodiments, the second thin film transistor TFT2 may further include a back-gate electrode BG. In one or more embodiments, the second thin film transistor TFT2 may further include a second source electrode S2 and a second drain electrode D2 connected to the second active layer ACT2. In one or more other embodiments, the two thin film transistors TFT2 may omit a separate second source electrode S2 and/or a separate second drain electrode D2, and may include a source electrode and/or a drain electrode integrally formed with the source region and/or the drain region of the second active layer ACT2.

The capacitor Cst may include a first capacitor electrode CAE1 and a second capacitor electrode CAE2. The first capacitor electrode CAE1 and the second capacitor electrode CAE2 may overlap with at least one insulating layer interposed therebetween.

For example, the first semiconductor layer SCL1 may be located on the buffer layer 122. The first semiconductor layer SCL1 may include the first active layer ACT1 of the first thin film transistor TFT1. For example, the first semiconductor layer SCL1 may include the first active layer ACT1 of each of the first, second, fifth, sixth, seventh, and/or eighth transistors T1, T2, T5, T6, T7, and/or T8.

The first active layer ACT1 may be included or provided in the first semiconductor layer SCL1, and may include a first semiconductor material (e.g., polysilicon). The first active layer ACT1 may include a channel region overlapping the first gate electrode G1, and a source region and a drain region located on respective sides of the channel region. In one or more embodiments, the source region and the drain region of the first active layer ACT1 may be connected to the first source electrode S1 and the first drain electrode D1, respectively. In one or more other embodiments, the source region and/or the drain region of the first active layer ACT1 may be the source electrode and/or the drain electrode of the first thin film transistor TFT1, respectively.

The first insulating layer 123 may be located on the first semiconductor layer SCL1. The first insulating layer 123 may cover the first semiconductor layer SCL1.

The first gate conductive layer GCDL1 may be located on the first insulating layer 123. The first gate conductive layer GCDL1 may include the first gate electrode G1 of the first thin film transistor TFT1. The first gate electrode G1 may be included or provided in the first gate conductive layer GCDL1 to overlap a part (e.g., a channel region) of the first active layer ACT1.

In one or more embodiments, the first gate conductive layer GCDL1 may further include at least one wire (or a part of the at least one wire), a conductive pattern (e.g., a bridge pattern), and/or a capacitor electrode. For example, the first gate conductive layer GCDL1 may further include the first capacitor electrode CAE1 of the capacitor Cst.

In one or more embodiments, the first capacitor electrode CAE1 may be integrally formed with the gate electrode of at least one first thin film transistor TFT1. For example, the first capacitor electrode CAE1 may be integrally formed with the gate electrode of the first transistor T1 illustrated in FIG. 4. For example, the first capacitor electrode CAE1 and the gate electrode of the first transistor T1 may be formed as one conductive pattern, and the second capacitor electrode CAE2 may be positioned to overlap the conductive pattern.

The second insulating layer 124 may be located on the first gate conductive layer GCDL1. The second insulating layer 124 may cover the first gate conductive layer GCDL1.

The second gate conductive layer GCDL2 may be located on the second insulating layer 124. The second gate conductive layer GCDL2 may include one electrode of the capacitor Cst, for example, the second capacitor electrode CAE2. In one or more embodiments, the second gate conductive layer GCDL2 may further include at least one electrode, a wire (or a part of the at least one wire), and/or a conductive pattern (e.g., a bridge pattern). For example, the second gate conductive layer GCDL2 may further include the back-gate electrode BG connected to the second gate electrode G2 of the second thin film transistor TFT2.

The third insulating layer 125 may be located on the second gate conductive layer GCDL2. The third insulating layer 125 may cover the second gate conductive layer GCDL2.

The second semiconductor layer SCL2 may be located on the third insulating layer 125. The second semiconductor layer SCL2 may include the second active layer ACT2 of the second thin film transistor TFT2. For example, the second semiconductor layer SCL2 may include the second active layer ACT2 of each of the third and fourth transistors T3 and T4 illustrated in FIG. 4.

The second active layer ACT2 may be included or provided in the second semiconductor layer SCL2, and may include a second semiconductor material (e.g., an oxide semiconductor) different from the first semiconductor material. For example, the second active layer ACT2 may include IGZO (indium (In), gallium (Ga), zinc (Zn) and oxygen (O)), IGZTO (indium (In), gallium (Ga), zinc (Zn), tin (Sn) and oxygen (O)), or IGTO (indium (In), gallium (Ga), tin (Sn), or oxygen (O)).

The second active layer ACT2 may include a channel region overlapping the second gate electrode G2, and a source region and a drain region located on respective sides of the channel region. In one or more embodiments, the source region and the drain region of the second active layer ACT2 may be connected to the second source electrode S2 and the second drain electrode D2, respectively. In one or more other embodiments, the source region and/or the drain region of the second active layer ACT2 may be the source electrode and/or the drain electrode of the second thin film transistor TFT2, respectively.

The fourth insulating layer 126 may be located on the second semiconductor layer SCL2. The fourth insulating layer 126 may cover the second gate conductive layer GCDL2 and the second semiconductor layer SCL2.

The third gate conductive layer GCDL3 may be located on the fourth insulating layer 126. The third gate conductive layer GCDL3 may include the second gate electrode G2 of the second thin film transistor TFT2. The second gate electrode G2 may be included or provided in the third gate conductive layer GCDL3 to overlap a part (e.g., a channel region) of the second active layer ACT2. In one or more embodiments, the third gate conductive layer GCDL3 may further include at least one wire (or a part of the at least one wire), a conductive pattern (e.g., a bridge pattern), and/or a capacitor electrode.

In one or more embodiments, each of the electrodes, the conductive patterns, and/or the wires included or provided in the lower conductive layer BCDL, the first gate conductive layer GCDL1, the second gate conductive layer GCDL2, and the third gate conductive layer GCDL3 may include a conductive material (e.g., molybdenum (Mo), aluminum (Al), chromium (Cr), gold (Au), titanium (Ti), nickel (Ni), neodymium (Nd), copper (Cu), or at least one of other metals, alloys thereof, or other conductive materials), and each may have a single-layer or multilayer structure. For example, each of the electrodes, the conductive patterns, and/or the wires provided in the lower conductive layer BCDL, the first gate conductive layer GCDL1, the second gate conductive layer GCDL2, and the third gate conductive layer GCDL3 may include molybdenum (Mo) or other metal materials. At least two conductive layers among the lower conductive layer BCDL, the first gate conductive layer GCDL1, the second gate conductive layer GCDL2, and the third gate conductive layer GCDL3 may include the same material or may include different materials. The materials of the lower conductive layer BCDL, the first gate conductive layer GCDL1, the second gate conductive layer GCDL2, and the third gate conductive layer GCDL3 are not limited, and may be variously changed according to one or more embodiments.

The fifth insulating layer 127 may be located on the third gate conductive layer GCDL3. The fifth insulating layer 127 may cover the third gate conductive layer GCDL3.

In one or more embodiments, the first insulating layer 123, the second insulating layer 124, the third insulating layer 125, the fourth insulating layer 126, and the fifth insulating layer 127 may be an inorganic insulating layer including an inorganic insulating material (e.g., silicon nitride, silicon oxide, silicon oxynitride, titanium oxide, aluminum oxide, or another inorganic insulating material), and each may have a single-layer or multilayer structure. At least two insulating layers among the first insulating layer 123, the second insulating layer 124, the third insulating layer 125, the fourth insulating layer 126, and the fifth insulating layer 127 may include the same material or may include different materials. Materials of each of the first insulating layer 123, the second insulating layer 124, the third insulating layer 125, the fourth insulating layer 126, and the fifth insulating layer 127 may be variously changed according to one or more embodiments.

The first source-drain conductive layer SCDL1 may be located on the fifth insulating layer 127. The first source-drain conductive layer SCDL1 may include the first source electrode S1 and the first drain electrode D1 of the first thin film transistor TFT1 (or at least one bridge electrode connected to the first source electrode S1 and/or the first drain electrode D1 of the first thin film transistor TFT1), and the second source electrode S2 and the second drain electrode D2 of the second thin film transistor TFT2 (or at least one bridge electrode connected to the second source electrode S2 and/or the second drain electrode D2 of the thin film transistor TFT2).

The first source electrode S1 of the first thin film transistor TFT1 may be connected to the source region of the first active layer ACT1. For example, the first source electrode S1 may be included or provided in the first source-drain conductive layer SCDL1, and may be connected to the source region of the first active layer ACT1 through the contact hole penetrating the first insulating layer 123, the second insulating layer 124, the third insulating layer 125, the fourth insulating layer 126, and the fifth insulating layer 127.

The first drain electrode D1 of the first thin film transistor TFT1 may be connected to the drain region of the first active layer ACT1. For example, the first drain electrode D1 may be included or provided in the first source-drain conductive layer SCDL1, and may be connected to the drain region of the first active layer ACT1 through the contact hole penetrating the first insulating layer 123, the second insulating layer 124, the third insulating layer 125, the fourth insulating layer 126, and the fifth insulating layer 127.

The second source electrode S2 of the second thin film transistor TFT2 may be connected to the source region of the second active layer ACT2. For example, the second source electrode S2 may be included or provided in the first source-drain conductive layer SCDL1, and may be connected to the source region of the second active layer ACT2 through the contact hole penetrating the fourth insulating layer 126 and the fifth insulating layer 127.

The second drain electrode D2 of the second thin film transistor TFT2 may be connected to the drain region of the second active layer ACT2. For example, the second drain electrode D2 may be included or provided in the first source-drain conductive layer SCDL1, and may be connected to the drain region of the second active layer ACT2 through the contact hole penetrating the fourth insulating layer 126 and the fifth insulating layer 127.

In one or more embodiments, the first source-drain conductive layer SCDL1 may further include at least one wire (or a part of the at least one wire), and/or a conductive pattern (e.g., a bridge pattern). For example, the first source-drain conductive layer SCDL1 may include a part of the power line PL (e.g., the first pixel power line VDL and/or the second pixel power line VSL) provided inside and/or outside the display area DA. In one or more embodiments, the first source-drain conductive layer SCDL1 may further include the first line LI1 and the second line LI2 (or a part of the first line LI1 and a part of the second line LI2).

The sixth insulating layer 128 may be located on the first source-drain conductive layer SCDL1. The sixth insulating layer 128 may cover the first source-drain conductive layer SCDL1.

The second source-drain conductive layer SCDL2 may be located on the sixth insulating layer 128. The second source-drain conductive layer SCDL2 may include the connection electrode CNE. The connection electrode CNE may be included or provided in the second source-drain conductive layer SCDL2, and may be connected to the first drain electrode D1 of the first thin film transistor TFT1 through the contact hole or the via hole penetrating the sixth insulating layer 128. In one or more embodiments, the second source-drain conductive layer SCDL2 may further include at least one wire (or a part of the at least one wire), and/or a conductive pattern (e.g., a bridge pattern). For example, the second source-drain conductive layer SCDL2 may include another part of the power line PL (e.g., the first pixel power line VDL and/or the second pixel power line VSL) provided inside and/or outside the display area DA.

In one or more embodiments, each of the electrodes, the conductive patterns, and/or the wires included or provided in the first source-drain conductive layer SCDL1 and the second source-drain conductive layer SCDL2 may include a conductive material (e.g., molybdenum (Mo), aluminum (Al), chromium (Cr), gold (Au), titanium (Ti), nickel (Ni), neodymium (Nd), copper (Cu), or at least one of other metals, alloys thereof, or other conductive materials), and may have a single-layer or multilayer structure. For example, each of the electrodes, the conductive patterns, and/or the wires included or provided in the first source-drain conductive layer SCDL1 and the second source-drain conductive layer SCDL2 may be formed as a triple-layer structure of titanium/aluminum/titanium (Ti/Al/Ti). The first source-drain conductive layer SCDL1 and the second source-drain conductive layer SCDL2 may include the same material or different materials. Materials of the first source-drain conductive layer SCDL1 and the second source-drain conductive layer SCDL2 may be variously changed according to one or more embodiments.

The seventh insulating layer 129 may be located on the second source-drain conductive layer SCDL2. The seventh insulating layer 129 may cover the second source-drain conductive layer SCDL2.

In one or more embodiments, the sixth insulating layer 128 and the seventh insulating layer 129 may be an organic insulating layer including an organic insulating material (e.g., acrylic resin, epoxy resin, phenolic resin, polyamide resin, polyimide resin, or other organic insulating material) to planarize the circuit layer 120, and each may have a single-layer or multilayer structure. The sixth insulating layer 128 and the seventh insulating layer 129 may include the same material or may include different materials. Materials of each of the sixth insulating layer 128 and the seventh insulating layer 129 may be variously changed according to one or more embodiments.

The light-emitting element layer 130 may be located on the circuit layer 120, and may be positioned in the display area DA. For example, the light-emitting element layer 130 may be located on the circuit layer 120 in the display area DA.

The light-emitting element layer 130 may include the light-emitting elements EL of the pixels PX. For example, the light-emitting element layer 130 may include a pixel-defining layer 131 for partitioning the emission area EA of each of the pixels PX and the light-emitting element EL located in each emission area EA. In one or more embodiments, the light-emitting element layer 130 may further include a spacer 132 located on a part of the pixel-defining layer 131.

Each of the light-emitting elements EL may include a first electrode ET1 (e.g., an anode electrode) connected to at least one transistor T (e.g., the first thin film transistor TFT1) included in the corresponding pixel PX through at least one connection electrode CNE, and the light-emitting layer EML and a second electrode ET2 (e.g., a cathode electrode) sequentially arranged on the first electrode ET1. In one or more embodiments, the light-emitting element EL may further include a first intermediate layer (e.g., hole layer including a hole transport layer) interposed between the first electrode ET1 and the light-emitting layer EML, and a second intermediate layer (e.g., an electron layer including an electron transport layer) interposed between the light-emitting layer EML and the second electrode ET2.

The first electrode ET1 of the light-emitting element EL may include a conductive material, and may be located on the circuit layer 120. For example, the first electrode ET1 may be located on the seventh insulating layer 129 to correspond to each emission area EA. The first electrode ET1 may be connected to the connection electrode CNE through the contact hole or the via hole penetrating the seventh insulating layer 129.

In one or more embodiments, the first electrode ET1 may include a metallic material having high reflectivity. For example, the first electrode ET1 may have a single-layer structure of molybdenum (Mo), titanium (Ti), copper (Cu), or aluminum (Al), or may have a multilayer structure (e.g., ITO/Mg, ITO/MgF, ITO/Ag, or ITO/Ag/ITO) including indium-tin-oxide (ITO), indium-zinc-oxide (IZO), zinc oxide (ZnO), indium oxide (In₂O₃) and silver (Ag), magnesium (Mg), aluminum (Al), platinum (Pt), lead (Pb), gold (Au), or nickel (in).

The light-emitting layer EML of the light-emitting element EL may include a high molecular material or a low molecular material. Light emitted from the light-emitting layer EML may contribute to image display. In one or more embodiments, the light-emitting layer EML may be provided for each pixel PX, and the light-emitting layer EML of each pixel PX may emit visible light of a color corresponding to the corresponding pixel PX. In one or more other embodiments, the light-emitting layer EML may be a common layer shared by pixels PX of different colors. A wavelength conversion layer and/or color filters corresponding to the color (or wavelength band) of light desired to be emitted from each pixel PX may be arranged in the emission areas EA of at least some of the pixels PX.

The second electrode ET2 of the light-emitting element EL includes a conductive material, and may be connected to the second pixel power line VSL. In one or more embodiments, the second electrode ET2 may be a common layer formed across the entire display area DA to cover the light-emitting layer EML and the pixel-defining layer 131. In one or more embodiments, the second electrode ET2 may be formed of a transparent conductive material (TCO), such as ITO or IZO capable of transmitting light or a semi-transmissive conductive material, such as magnesium (Mg), silver (Ag), or an alloy of magnesium (Mg) and silver (Ag).

The pixel-defining layer 131 may have an opening corresponding to each of the emission areas EA and may surround the emission areas EA. For example, the pixel-defining layer 131 may be formed to cover an edge of the first electrode ET1 of the light-emitting element EL, and may include an opening exposing the remaining portion of the first electrode ET1. A region where the exposed first electrode ET1 and the light-emitting layer EML overlap (or a region including the same) may be defined as the emission area EA of each pixel PX.

In one or more embodiments, the pixel-defining layer 131 may include at least one organic layer containing an organic insulating material. For example, the pixel-defining layer 131 may include acrylic resin, epoxy resin, phenolic resin, polyamide resin, polyimide resin, unsaturated polyester resin, polyphenylene ether resin, polyphenylenesulfide resin, benzocyclobutene (BCB), or other organic insulating materials.

The spacer 132 may be located on a part of the pixel-defining layer 131. The spacer 132 may include at least one organic layer containing an organic insulating material. The spacer 132 may include the same material as the pixel-defining layer 131, or may include a different material from the pixel-defining layer 131. In one or more embodiments, the pixel-defining layer 131 and the spacer 132 may be sequentially formed through separate mask processes. In one or more other embodiments, the pixel-defining layer 131 and the spacer 132 may be simultaneously formed using a halftone mask. In this case, the pixel-defining layer 131 and the spacer 132 may be integral with each other to be regarded as a single insulating layer. The organic insulating material constituting the spacer 132 is not particularly limited, and may be variously changed according to one or more embodiments.

The encapsulation layer 140 may be located on the light-emitting element layer 130 in the main region MA. The encapsulation layer 140 may cover the light-emitting element layer 130, and may extend to the non-display area NA to be in contact with the circuit layer 120. For example, the encapsulation layer 140 may be in the display area DA and the non-display area NA to cover the light-emitting element layer 130. The encapsulation layer 140 may block the permeation of oxygen or moisture into the light-emitting element layer 130, and may reduce electrical and/or physical impacts to the circuit layer 120 and the light-emitting element layer 130.

In one or more embodiments, the encapsulation layer 140 may include a first inorganic encapsulation layer 141, an organic encapsulation layer 142, and a second inorganic encapsulation layer 143 sequentially arranged on the light-emitting element layer 130. The first inorganic encapsulation layer 141 and the second inorganic encapsulation layer 143 may include an inorganic material, and the organic encapsulation layer 142 may include an organic material.

In one or more embodiments, the organic encapsulation layer 142 may be prepared by dropping an organic material in a liquid state onto the first inorganic encapsulation layer 141, spreading it to cover the display area DA, and then curing it. The display panel 100 may further include at least one dam for limiting the diffusion range of the organic material of the organic encapsulation layer 142. The dam may be in the non-display area NA adjacent to the display area DA so as to surround the display area DA.

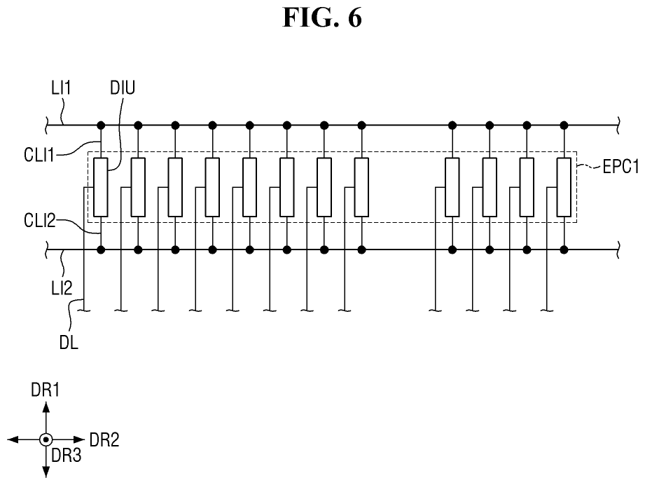

FIG. 6 is a plan view schematically showing the first electrostatic discharge circuit EPC1 according to one or more embodiments.

Referring to FIG. 6 in addition to FIGS. 1 to 5, the first electrostatic discharge circuit EPC1 may be connected to the first line LI1 and the second line LI2 through a first connection line CLI1 and a second connection line CLI2, respectively. For example, the display panel 100 may further include the first connection line CLI1 connected between the first line LI1 and the first electrostatic discharge circuit EPC1, and the second connection line CLI2 connected between the second line LI2 and the first electrostatic discharge circuit EPC1.

In one or more embodiments, the first electrostatic discharge circuit EPC1 may be spaced apart from the first line LI1 and the second line LI2 by the same distance. For example, the first line LI1 and the second line LI2 may pass through the vicinity of the first electrostatic discharge circuit EPC1 while being spaced apart from each other with the first electrostatic discharge circuit EPC1 interposed therebetween, and the first electrostatic discharge circuit EPC1 may be spaced apart from the first line LI1 and the second line LI2 by the same distance.

The first electrostatic discharge circuit EPC1 may include diode units DIU connected to the data lines DL. Each diode unit DIU may be connected to one data line DL, and may be connected to the first line LI1 and the second line LI2 through the first connection line CLI1 and the second connection line CLI2, respectively.

In one or more embodiments, each diode unit DIU may be spaced apart from the first line LI1 and the second line LI2 by the same distance. For example, each diode unit DIU may be located at an intermediate point between the first line LI1 and the second line LI2. For example, in the first direction DR1, each diode unit DIU may be spaced apart from the first line LI1 and the second line LI2 by the same distance.

In accordance with the above-described embodiments, the damage to the first electrostatic discharge circuit EPC1 due to static electricity that may be generated or introduced during the manufacturing process of the display panel 100 may be reduced or prevented by connecting the first electrostatic discharge circuit EPC1 to the first line LI1 and the second line LI2 through the first connection line CLI1 and the second connection line CLI2 without directly connecting the first electrostatic discharge circuit EPC1 to the first line LI1 and the second line LI2. Accordingly, it is possible to reduce or prevent defects, such as short-circuit defects or the like from occurring between each data line DL and the first line LI1 and/or the second line LI2.

FIG. 7 is a circuit diagram showing the diode unit DIU according to one or more embodiments. For example, FIG. 7 is a circuit diagram showing an equivalent circuit of the diode unit DIU of FIG. 6.

Referring to FIG. 7 in addition to FIGS. 1 to 6, each diode unit DIU may include diodes DI connected between the first line LI1 and the second line LI2 through the first connection line CLI1 and the second connection line CLI2. The node between the diodes DI may be connected to the data line DL. For example, each diode unit DIU may include a first diode DI1 connected between the first connection line CLI1 and the data line DL, and a second diode DI2 connected between the second connection line CLI2 and the data line DL.

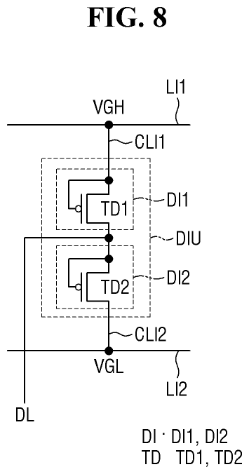

FIG. 8 is a circuit diagram showing the diode unit DIU according to one or more embodiments. For example, FIG. 8 is a circuit diagram showing the diode unit DIU of FIGS. 6 and 7.

Referring to FIG. 8 in addition to FIGS. 1 to 7, each diode DI may include a diode-connected transistor TD.

The first diode DI1 may include a first transistor TD1 diode-connected between the first connection line CLI1 and the data line DL. For example, the first transistor TD1 may be a diode-connected thin film transistor in which a gate electrode is connected to a source electrode or a drain electrode.

In one or more embodiments, the first diode DI1 may be diode-connected in the reverse direction between the first connection line CLI1 and the data line DL. For example, the gate electrode of the first diode DI1 may be connected to the source electrode connected to the first connection line CLI1.

The second diode DI2 may include a second transistor TD2 diode-connected between the second connection line CLI2 and the data line DL. For example, the second diode DI2 may be a diode-connected thin film transistor in which a gate electrode is connected to a source electrode or a drain electrode.

In one or more embodiments, the second diode DI2 may be diode-connected in the reverse direction between the second connection line CLI2 and the data line DL. For example, the gate electrode of the second diode DI2 may be connected to the source electrode connected to the data line DL.

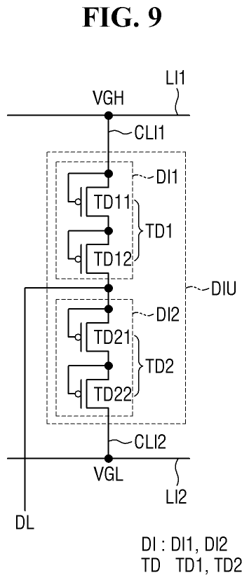

FIG. 9 is a circuit diagram showing the diode unit DIU according to one or more embodiments.

Referring to FIG. 9 in addition to FIGS. 1 to 8, each diode DI may include at least two diode-connected transistors TD. For example, the first diode DI1 may include the first transistors TD1 (for example, an eleventh transistor TD11 and a twelfth transistor TD12) connected in series between the first connection line CLI1 and the data line DL. The second diode DI2 may include the second transistors TD2 (for example, a twenty-first transistor TD21 and a twenty-second transistor TD22) connected in series between the second connection line CLI2 and the data line DL.

In accordance with the embodiments of FIGS. 8 and 9, each diode DI may include at least one diode-connected transistor TD. The type, number, and/or connection structure of the transistors TD constituting each diode DI may be variously changed according to one or more embodiments.

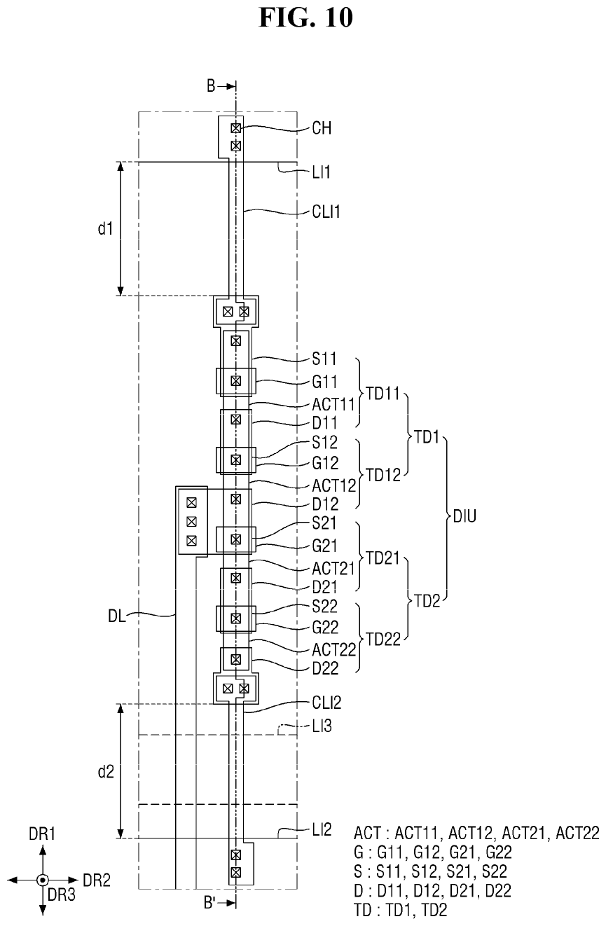

FIG. 10 is a plan view showing the diode unit DIU according to one or more embodiments. For example, FIG. 10 is a plan view showing the diode unit DIU of FIG. 9.

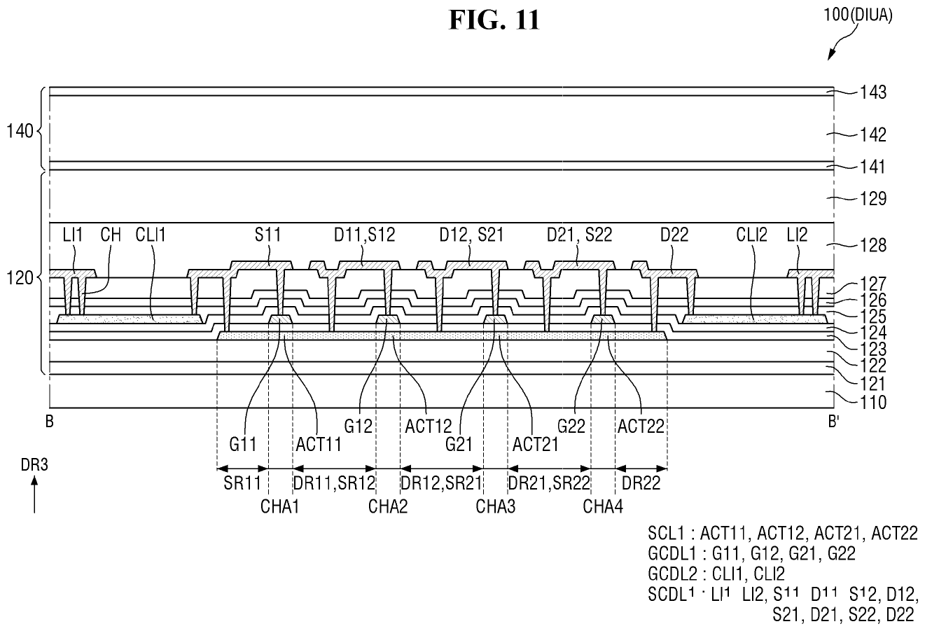

FIG. 11 is a cross-sectional view showing the diode unit DIU according to one or more embodiments. For example, FIG. 11 shows the cross section of a diode unit area DIUA where each diode unit DIU is located, and shows the cross section of the diode unit DIU taken along the line B-B′ of FIG. 10.

Referring to FIGS. 10 and 11 in addition to FIGS. 1 to 9, each diode-connected transistor TD may include the active layer ACT, the gate electrode G, the source electrode S, and the drain electrode D. The active layer ACT may be connected to the source electrode S and the drain electrode D of the transistor TD. The gate electrode G may be connected to one electrode (for example, the source electrode S) of the transistor TD.

At least two elements provided on different layers and connected to each other may be electrically connected to each other through at least one contact hole CH. The shape, position, and/or number of the contact holes CH may be changed according to one or more embodiments. In FIGS. 10 and 11, only one contact hole CH is denoted by a notation.

In one or more embodiments, the diode unit DIU may include the eleventh transistor TD11, the twelfth transistor TD12, the twenty-first transistor TD21, and the twenty-second transistor TD22 connected in series between the first line LI1 and the second line LI2. The eleventh transistor TD11 may be connected to the first line LI1 via the first connection line CLI1 provided in a conductive layer different from a conductive layer in which the first line LI1 and the source electrode S11 of the eleventh transistor TD11 are provided. The twenty-second transistor TD22 may be connected to the second line LI2 via the second connection line CLI2 provided in a conductive layer that is different from a conductive layer in which the second line LI2 and the drain electrode D22 of the twenty-second transistor TD22 are provided.

The eleventh transistor TD11 may include an active layer ACT11, a gate electrode G11, a source electrode S11, and a drain electrode D11. The active layer ACT11 of the eleventh transistor TD11 may include a channel region (hereinafter, referred to as “first channel region”) CHA1 overlapping the gate electrode G11, a source region SR11 located at one side of the first channel region CHA1 and connected to the source electrode S11, and a drain region DR11 located at the other side of the first channel region CHA1 and connected to the drain electrode D11. In one or more embodiments, the drain region DR11 of the eleventh transistor TD11, and the source region SR12 of the twelfth transistor TD12, may be integrated with each other. The gate electrode G11 of the eleventh transistor TD11 may be connected to the source electrode S11. The source electrode S11 of the eleventh transistor TD11 may be connected to the first connection line CLI1. The drain electrode D11 of the eleventh transistor TD11 may be connected to the source electrode S12 of the twelfth transistor TD12. In one or more embodiments, the drain electrode D11 of the eleventh transistor TD11 and the source electrode S12 of the twelfth transistor TD12 may be integrated with each other.

The twelfth transistor TD12 may include an active layer ACT12, a gate electrode G12, a source electrode S12, and a drain electrode D12. The active layer ACT12 of the twelfth transistor TD12 may include a channel region (hereinafter, referred to as “second channel region”) CHA2 overlapping the gate electrode G12, a source region SR12 located at one side of the second channel region CHA2 and connected to the source electrode S12, and a drain region DR12 located at the other side of the second channel region CHA2 and connected to the drain electrode D12. In one or more embodiments, the drain region DR12 of the twelfth transistor TD12, and the source region SR21 of the twenty-first transistor TD21, may be integrated with each other. The gate electrode G12 of the twelfth transistor TD12 may be connected to the source electrode S12. The source electrode S12 of the twelfth transistor TD12 may be connected to the drain electrode D11 of the eleventh transistor TD11. The drain electrode D12 of the twelfth transistor TD12 may be connected to the source electrode S21 of the twenty-first transistor TD12. In one or more embodiments, the drain electrode D12 of the twelfth transistor TD12 and the source electrode S21 of the twenty-first transistor TD12 may be integrated with each other.

The twenty-first transistor TD21 may include an active layer ACT21, a gate electrode G21, a source electrode S21, and a drain electrode D21. The active layer ACT21 of the twenty-first transistor TD21 may include a channel region (hereinafter, referred to as “third channel region”) CHA3 overlapping the gate electrode G21, a source region SR21 located at one side of the third channel region CHA3 and connected to the source electrode S21, and a drain region DR21 located at the other side of the third channel region CHA3 and connected to the drain electrode D21. In one or more embodiments, the drain region DR21 of the twenty-first transistor TD21 and the source region SR22 of the twenty-second transistor TD22 may be integrated with each other. The gate electrode G21 of the twenty-first transistor TD21 may be connected to the source electrode S21. The source electrode S21 of the twenty-first transistor TD21 may be connected to the drain electrode D12 of the twelfth transistor TD12. The drain electrode D21 of the twenty-first transistor TD21 may be connected to the source electrode S22 of the twenty-second transistor TD22. In one or more embodiments, the drain electrode D21 of the twenty-first transistor TD21 and the source electrode S22 of the twenty-second transistor TD22 may be integrated with each other.

The twenty-second transistor TD22 may include an active layer ACT22, a gate electrode G22, a source electrode S22, and a drain electrode D22. The active layer ACT22 of the twenty-second transistor TD22 may include a channel region (hereinafter, referred to as “fourth channel region”) CHA4 overlapping the gate electrode G22, a source region SR22 located at one side of the fourth channel region CHA4 and connected to the source electrode S22, and a drain region DR22 located at the other side of the fourth channel region CHA4 and connected to the drain electrode D22. The gate electrode G22 of the twenty-second transistor TD22 may be connected to the source electrode S22. The source electrode S22 of the twenty-second transistor TD22 may be connected to the drain electrode D21 of the twenty-first transistor TD21. The drain electrode D22 of the twenty-second transistor TD22 may be connected to the second connection line CLI2.

The data line DL may be connected to the twelfth transistor TD12 and the twenty-first transistor TD21. For example, the data line DL may be connected to the drain electrode D12 of the twelfth transistor TD12 and the source electrode S21 of the twenty-first transistor TD21.

The transistors TD, the data line DL, the first line LI1, the second line LI2, the first connection line CLI1, and the second connection line CLI2 may be included or provided in the circuit layer 120 of the display panel 100.

The active layers ACT of the transistors TD may be included or provided in the semiconductor layer provided in the circuit layer 120. For example, the active layers ACT of the transistors TD may be included or provided in the first semiconductor layer SCL1 located on the substrate 110.

The gate electrodes G of the transistors TD may be included or provided in the conductive layer provided in the circuit layer 120. For example, the gate electrodes G of the transistors TD may be included or provided in the first gate conductive layer GCDL1 located on the first insulating layer 123 covering the active layers ACT.

The source electrodes S and the drain electrodes D of the transistors TD may be included or provided in the conductive layer provided in the circuit layer 120. For example, the source electrodes S and the drain electrodes D of the transistors TD may be included or provided in the first source-drain conductive layer SCDL1 located on the fifth insulating layer 127. The fifth insulating layer 127 may cover the conductive layers thereunder, for example, the first gate conductive layer GCDL1, the second gate conductive layer GCDL2, and the third gate conductive layer GCDL3.

The data line DL may be included or provided in at least one conductive layer provided in the circuit layer 120. For example, in the vicinity of the first electrostatic discharge circuit EPC1, the data line DL may be included or provided in the first gate conductive layer GCDL1, the second gate conductive layer GCDL2, and the third gate conductive layer GCDL3 (for example, the third gate conductive layer GCDL3 including the second gate electrode G2 of FIG. 5).

The first line LI1 and the second line LI2 may be included or provided in at least one conductive layer provided in the circuit layer 120. For example, in the vicinity of the first electrostatic discharge circuit EPC1, the first line LI1, and the second line LI2 may be included or provided in the first source-drain conductive layer SCDL1 together with the source electrodes S and the drain electrodes D of the transistors TD, and may be spaced apart from the source electrodes S and drain electrodes D of the transistors TD.

The first connection line CLI1 and the second connection line CLI2 may be included or provided in the conductive layer provided in the circuit layer 120. In one or more embodiments, the first connection line CLI1 and the second connection line CLI2 may be under the wires and electrodes connected thereto. For example, the first connection line CLI1 and the second connection line CLI2 may be under the first line LI1, the second line LI2, and the source electrode S11 of the eleventh transistor TD11 and the drain electrode D22 of the twenty-second transistor TD22 on the substrate 110. For example, the first connection line CLI1 and the second connection line CLI2 may be included or provided in the second gate conductive layer GCDL2 located on the second insulating layer 124 covering the first gate conductive layer GCDL1.

In accordance with the above-described embodiments, the first line LI1 and the second line LI2 may not be directly connected to the diode unit DIU, and may be connected to the diode unit DIU by a cut-and-short structure or a jumping structure through the first connection line CLI1 and the second connection line CLI2 located thereunder. Accordingly, it is possible to reduce or prevent damage to the first electrostatic discharge circuit EPC1 due to static electricity that may occur during the manufacturing process of the display panel 100. For example, it is possible to reduce or prevent short-circuit defects between the first line LI1 and the data line DL, which may otherwise occur due to the damage (for example, electrostatic breakdown caused by plasma charge introduced from the upper side of the display panel 100 that is being manufactured) of the active layer ACT of the first transistor TD1 due to static electricity generated during an etching process for forming the first source-drain conductive layer SCDL1. Further, even while the display device 10 is being used, the damage due to static electricity may be reduced or prevented by the first electrostatic discharge circuit EPC1.

Further, in accordance with the above-described embodiments, the first line LI1 and the second line LI2 are not formed integrally with one electrode of the first transistor TD1 and one electrode of the second transistor TD2, respectively, so that the first line LI1 and the second line LI2 may not be formed in a pattern protruding toward each diode unit DIU. Accordingly, it is possible to prevent or reduce the inflow of static electricity from the outside during the manufacturing process of the display panel 100, and the usage of the display device 10 including the display panel 100.

In one or more embodiments, the first diode DI1 including at least one first transistor TD1 (for example, the eleventh transistor TD11 and the twelfth transistor TD12) may be spaced apart from the first line LI1 by a distance d1 (e.g., see FIG. 10). The first connection line CLI1 may have a length corresponding to the first distance d1.

Similarly, the second diode DI2 including at least one second transistor TD2 (for example, the twenty-first transistor TD21 and the twenty-second transistor TD22) may be spaced apart from the second line LI2 by a second distance d2 (e.g., see FIG. 10). The second connection line CLI2 may have a length corresponding to the second distance d2.

In one or more embodiments, the first distance d1 and the second distance d2 may be substantially the same. For example, the first distance d1 and the second distance d2 may have substantially the same value within a range of an allowable error that may occur during the manufacturing process. In one or more embodiments, when the display panel 100 includes a third line LI3 (e.g., see FIG. 10) passing through the vicinity of the first line LI1 and/or the second line LI2 (for example, the area between the first line LI1 and the second line LI2), the arrangement position of the diode unit DIU may be appropriately set and/or adjusted in consideration of the separation distance for ensuring electrical stability between the first line LI1 and/or the second line LI2 and the third line LI3.

In accordance with the above-described embodiments, the diode units DIU provided on the first electrostatic discharge circuit EPC1 may be spaced apart from the first line LI1 and the second line LI2 by a substantially equal distance. Accordingly, the difference in electric field applied to each diode DI may be reduced, and the damage to the diode DI may be reduced or prevented. Accordingly, it is possible to prevent or reduce the damage to the display device 10 due to static electricity during the manufacturing process and the usage of the display device 10.

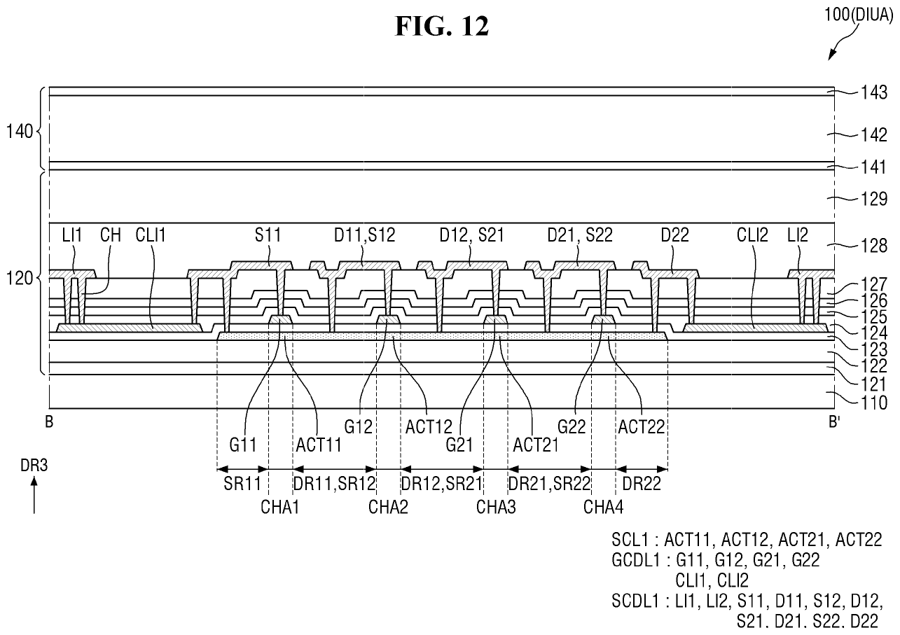

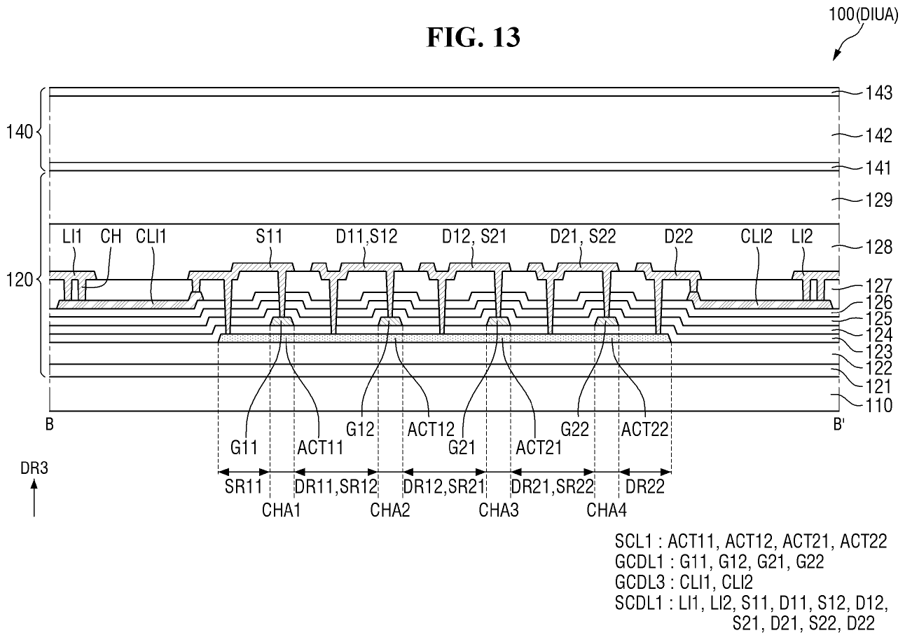

FIG. 12 is a cross-sectional view showing the diode unit DIU according to one or more embodiments. FIG. 13 is a cross-sectional view showing the diode unit DIU according to one or more embodiments. For example, FIGS. 12 and 13 show the cross section of the diode unit DIU taken along the line B-B′ of FIG. 10, and show different modified embodiments of the one or more embodiments corresponding to FIG. 11 in relation to the first connection line CLI1 and the second connection line CLI2.

Referring to FIGS. 12 and 13 in addition to FIGS. 1 to 11, the first connection line CLI1 and the second connection line CLI2 may be included or provided in a gate conductive layer different from the second gate conductive layer GCDL2. For example, the first connection line CLI1 and the second connection line CLI2 may be included or provided in the first gate conductive layer GCDL1 as shown in FIG. 12, or may be included or provided in the third gate conductive layer GCDL3 as shown in FIG. 13. In addition to the above-described embodiments, the positions of the first connection line CLI1 and the second connection line CLI2 may be variously changed according to one or more embodiments.

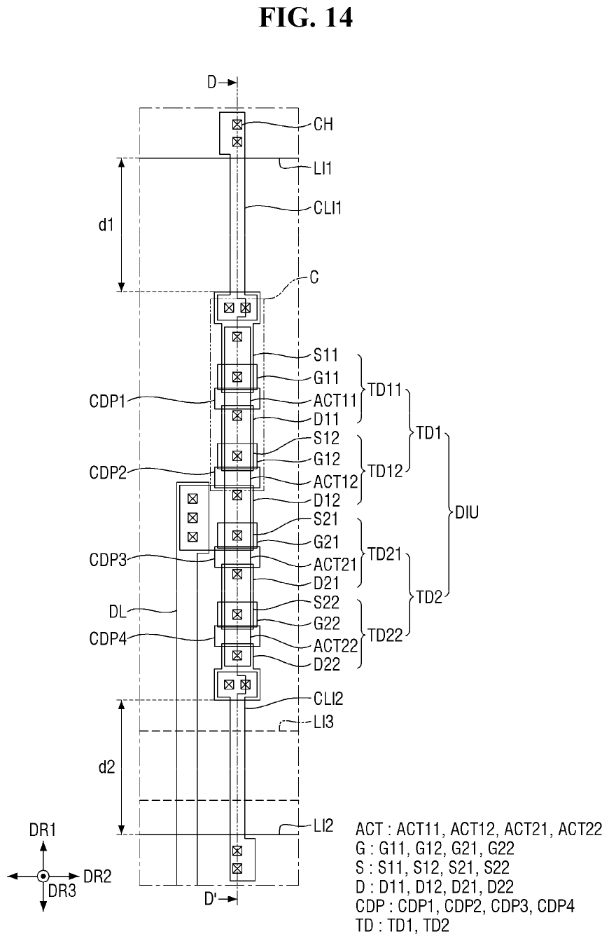

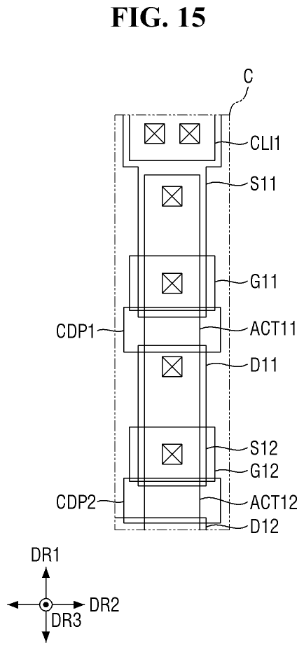

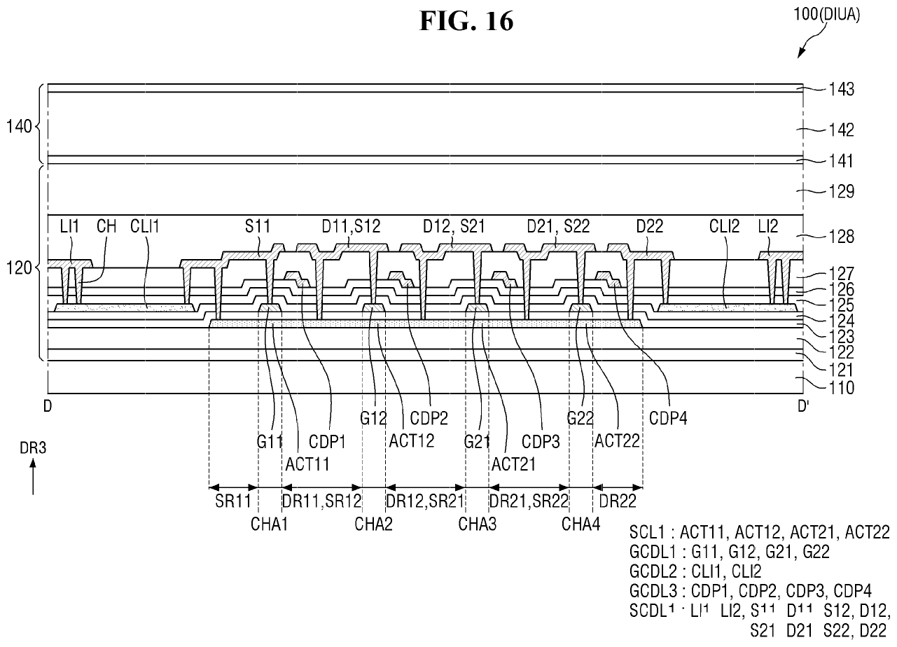

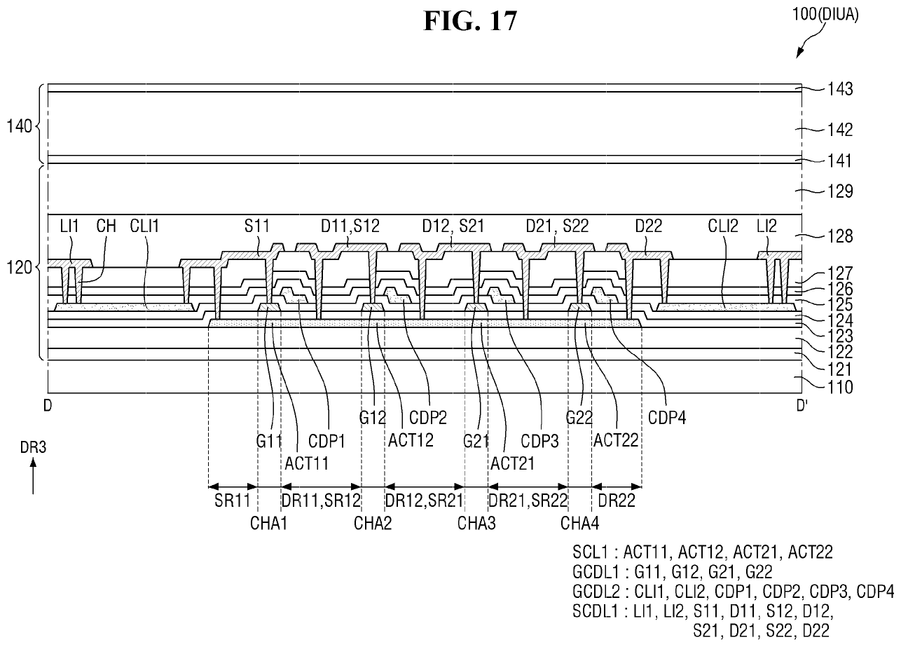

FIG. 14 is a plan view showing the diode unit DIU according to one or more embodiments. FIG. 15 is an enlarged plan view showing area C of FIG. 14. FIG. 16 is a cross-sectional view showing the diode unit DIU according to one or more embodiments. FIG. 17 is a cross-sectional view showing the diode unit DIU according to one or more embodiments. For example, FIGS. 16 and 17 show the cross section of the diode unit area DIUA where each diode unit DIU is located, and show different embodiments of the cross section of the diode unit DIU taken along the line D-D′ of FIG. 14. FIGS. 14 to 17 show additional embodiments of the one or more embodiments corresponding to FIGS. 10 and 11.

Referring to FIGS. 14 to 17 in addition to FIGS. 1 to 13, the first electrostatic discharge circuit EPC1 may further include conductive patterns CDP provided in each diode unit area DIUA. The conductive patterns CDP may be located at positions corresponding to the separation space (or open portion) between the source electrode S and the drain electrode D of each of the transistors TD forming each diode unit DIU. For example, the first electrostatic discharge circuit EPC1 may include a first conductive pattern CDP1 overlapping the separation space between the source electrode S11 and the drain electrode D11 of the eleventh transistor TD11, a second conductive pattern CDP2 overlapping the separation space between the source electrode S12 and the drain electrode D12 of the twelfth transistor TD12, a third conductive pattern CDP3 overlapping the separation space between the source electrode S21 and the drain electrode D21 of the twenty-first transistor TD21, and a fourth conductive pattern CDP4 overlapping the separation space between the source electrode S22 and the drain electrode D22 of the twenty-second transistor TD22.

In one or more embodiments, the conductive patterns CDP may be located under the source electrodes S and the drain electrodes D of the transistors TD on the substrate 110. The conductive patterns CDP may be located above the active layers ACT of the transistors TD on the substrate 110. For example, the conductive patterns CDP may be included or provided in the third gate conductive layer GCDL3 as shown in FIG. 16, or may be included or provided in the second gate conductive layer GCDL2 as shown in FIG. 17. The conductive patterns CDP may cover the active layers ACT of the transistors TD in the separation space between the source electrode S and the drain electrode D of each of the transistors TD. The conductive patterns CDP may be floating, or may be connected to a wire to which a constant voltage is applied.

The conductive patterns CDP may screen a charge path that may occur in the open portion between the source electrode S and the drain electrode D of each of the transistors TD. Accordingly, damage to the transistors TD due to static electricity may be reduced or prevented. Accordingly, damage to the diode unit DIU due to static electricity may be prevented or reduced, and defects of the display device 10 may be reduced or prevented.

In one or more embodiments, the conductive patterns CDP may overlap the gate electrode G, the source electrode S, and the drain electrode D of each of the transistors TD to completely cover the active layer ACT of each of the transistors TD when viewed from the top of the display panel 100. Accordingly, the conductive patterns CDP may more stably and/or effectively protect the transistors TD from static electricity.

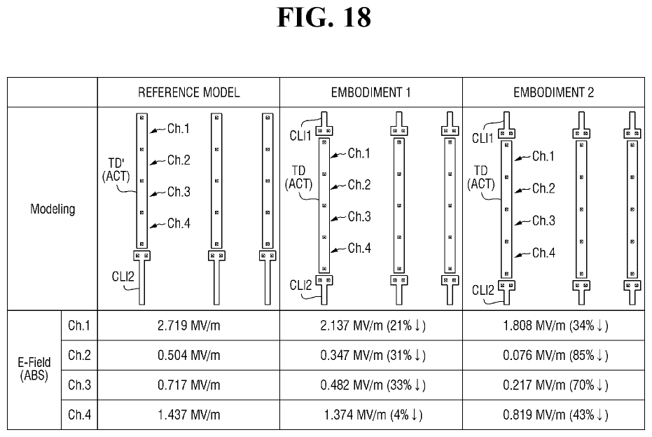

FIG. 18 is simulation data showing the intensity of the electric field applied to each channel of the first electrostatic discharge circuit EPC1 according to one or more embodiments. For example, FIG. 18 is simulation data showing electrostatic discharge test results of a reference model to which the embodiments are not applied and models to which the structure according to one or more embodiments is applied.

Referring to FIG. 18 in addition to FIGS. 1 to 17, the intensity of the electric field applied to each channel of the diode unit DIU is lower in a model in accordance with one or more first embodiments (for example, the display panel 100 including the first electrostatic discharge circuit EPC1 in which the transistor TD is connected to the first line LI1 through the first connection line CLI1), compared to a reference model (for example, the display panel including the first electrostatic discharge circuit EPC1 in which the transistor TD' is directly connected to the first line LI1). For example, the intensities of the electric fields measured in a first channel Ch.1 corresponding to the first channel region CHA1, a second channel Ch.2 corresponding to the second channel region CHA2, a third channel Ch.3 corresponding to the third channel region CHA3, and a fourth channel Ch.4 corresponding to the fourth channel region CHA4 are lower in the model according to the one or more first embodiments, compared to the reference model. Further, the intensity of the electric field applied to each channel is even lower in a model according to one or more second embodiments having conductive patterns CDP in addition to the structure of the one or more first embodiments, compared to the model according to the one or more first embodiments. Therefore, by applying the structure according to the embodiments, it is possible to prevent or reduce damage (for example, electrostatic breakdown) to each channel of the diode unit DIU due to static electricity during the manufacturing process of the display device 10.

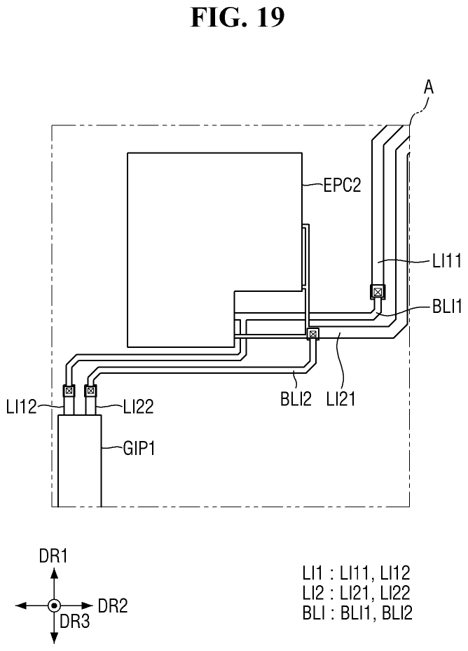

FIG. 19 is a plan view showing area A of FIG. 3. For example, FIG. 19 schematically shows the first line LI1 and the second line LI2 in area A of FIG. 3 in relation to the routing structure of the first line LI1 and the second line LI2 according to one or more embodiments.

Referring to FIG. 19 in addition to FIGS. 1 to 18, the first line LI1 may include a first line portion LI11 connected to the first electrostatic discharge circuit EPC1, and a second line portion LI12 connected to the first gate-driving circuit GIP1 and spaced apart from the first line portion LI11. For example, the first line portion LI11 and the second line portion LI12 of the first line LI1 may be included or provided in the same conductive layer (for example, the first source-drain conductive layer SCDL1) of the circuit layer 120, and may be physically disconnected. The first line portion LI11 and the second line portion LI12 of the first line LI1 may be electrically connected to each other through a first bridge line BLI1.

The first bridge line BLI1 may connect the first line portion LI11 and the second line portion LI12 of the first line LI1. The first bridge line BLI1 may be under the first line LI1 (for example, the first line portion LI11 and the second line portion LI12) on the substrate 110. For example, the first bridge line BLI1 may be included or provided in the first gate conductive layer GCDL1, the second gate conductive layer GCDL2, or the third gate conductive layer GCDL3. When the first bridge line BLI1 is considered as a part of the first line LI1, the first line portion LI11 and the second line portion LI12 of the first line LI1 may be an upper line portion of the first line LI1, and the first bridge line BLI1 may be a lower line portion of the first line LI1.

The second line LI2 may include a first line portion LI21 connected to the first electrostatic discharge circuit EPC1, and a second line portion LI22 connected to the first gate-driving circuit GIP1 and spaced apart from the first line portion LI21. For example, the first line portion LI21 and the second line portion LI22 of the second line LI2 may be included or provided in the same conductive layer (for example, the first source-drain conductive layer SCDL1) of the circuit layer 120, and may be physically disconnected. The first line portion LI21 and the second line portion LI22 of the second line LI2 may be electrically connected to each other through a second bridge line BLI2.

The second bridge line BLI2 may connect the first line portion LI21 and the second line portion LI22 of the second line LI2. The second bridge line BLI2 may be under the second line LI2 (for example, the first line portion LI21 and the second line portion LI22) on the substrate 110. For example, the second bridge line BLI2 may be included or provided in the first gate conductive layer GCDL1, the second gate conductive layer GCDL2, or the third gate conductive layer GCDL3. When the second bridge line BLI2 is considered as a part of the second line LI2, the first line portion LI21 and the second line portion LI22 of the second line LI2 may be an upper line portion of the second line LI2, and the second bridge line BLI2 may be a lower line portion of the second line LI2.

In accordance with the above-described embodiments, at the edge portion of the display panel 100 where the second electrostatic discharge circuit EPC2 and the like are located, the first line portions LI11 and LI21 and the second line portions LI12 and LI22 of the first line LI1 and the second line LI2 provided in the upper conductive layer (for example, the first source-drain conductive layer SCDL1) that is relatively susceptible to static electricity may be physically disconnected. Further, the first line portion LI11 and the second line portion LI12 of the first line LI1 may be connected to each other, and the first line portion LI21 and the second line portion LI22 of the second line LI2 may be connected to each other, through respective bridge lines BLI provided in the conductive layer (for example, the gate conductive layer) located further under the substrate 110. For example, the first line portions LI11 and LI21 and the second line portions LI12 and LI22 of the first line LI1 and the second line LI2 may be formed on the substrate 110 on which the first bridge line BLI1 and the second bridge line BLI2 are already formed. Accordingly, even if static electricity is introduced during the manufacturing process of the display device 10, it may be quickly discharged to reduce or prevent damage to the first electrostatic discharge circuit EPC1 or the like. In accordance with the above-described embodiments, it is possible to effectively reduce or prevent damage to the display device 10 due to static electricity that may be introduced through the upper conductive layer during the manufacturing process and the usage of the display device 10.

The structure of the first line LI1 and the second line LI2 according to the one or more embodiments corresponding to FIG. 19 may be applied alone to the display device 10, or may be applied to the display device 10 together with at least one of the above-described embodiments. Even if only the structure of the first line LI1 and the second line LI2 according to the one or more embodiments corresponding to FIG. 19 is applied, damage to the display device 10 due to static electricity may be effectively prevented or reduced. When the structures of the one or more embodiments corresponding to FIG. 19 and at least one of the above-described embodiments are simultaneously applied to the display device 10, damage to the display device 10 due to static electricity may be more effectively prevented or reduced.

In concluding the detailed description, those skilled in the art will appreciate that many variations and modifications can be made to the embodiments without substantially departing from the aspects of the present disclosure. Therefore, the disclosed embodiments of the present disclosure are used in a generic and descriptive sense only and not for purposes of limitation.

What is claimed is:

1. A display device comprising:
a substrate comprising a display area and a non-display area;
pixels in the display area above the substrate;
an electrostatic discharge circuit in the non-display area above the substrate;
a first line in the non-display area above the substrate, and configured to receive a first voltage;
a second line in the non-display area above the substrate, and configured to receive a second voltage that is lower than the first voltage;
a first connection line connected between the first line and the electrostatic discharge circuit under the first line on the substrate; and
a second connection line connected between the second line and the electrostatic discharge circuit under the second line on the substrate.

2. The display device of claim 1, wherein the first line and the second line are spaced from each other with the electrostatic discharge circuit therebetween, and
wherein the electrostatic discharge circuit is spaced from the first line and the second line by a same distance.

3. The display device of claim 1, further comprising data lines extending from the non-display area to the display area, and connected to the pixels,
wherein first ends of the data lines are connected to the electrostatic discharge circuit.

4. The display device of claim 3, wherein the electrostatic discharge circuit comprises diode units respectively connected to the data lines, the diode units comprising:
a first diode connected between the first connection line and the one of the data lines, and spaced from the first line by a first distance; and
a second diode connected between the second connection line and the one of the data lines, and spaced from the second line by a second distance.

5. The display device of claim 4, wherein the first distance and the second distance are substantially equal to each other.

6. The display device of claim 4, wherein the first diode comprises a first transistor diode-connected between the first connection line and the one of the data lines, and
wherein the second diode comprises a second transistor diode-connected between the one of the data lines and the second connection line.

7. The display device of claim 6, wherein the diode units comprise a first transistor and a second transistor, the first transistor and the second transistor comprising:
an active layer above the substrate;
a gate electrode above an insulating layer covering the active layer; and
a source electrode and a drain electrode above another insulating layer covering the gate electrode and spaced apart from each other.

8. The display device of claim 7, further comprising conductive patterns overlapping a separation space between the source electrode and the drain electrode, beneath the source electrode and the drain electrode.

9. The display device of claim 8, wherein the conductive patterns cover the active layer in a separation space between the source electrode and the drain electrode.

10. The display device of claim 8, wherein the conductive patterns overlap the gate electrode, the source electrode, and the drain electrode.

11. The display device of claim 8, wherein the gate electrode is provided in a first gate conductive layer above the active layer, and
wherein the conductive patterns are provided in a second gate conductive layer above an insulating layer covering the first gate conductive layer, or provided in a third gate conductive layer above an insulating layer covering the second gate conductive layer.

12. The display device of claim 7, further comprising a circuit layer above the substrate, and provided with the first transistor and the second transistor, the first line, the second line, the first connection line, and the second connection line, the circuit layer comprising:
a semiconductor layer above the substrate, and comprising the active layer;
a first gate conductive layer above an insulating layer covering the semiconductor layer, and comprising the gate electrode;
a second gate conductive layer above an insulating layer covering the first gate conductive layer; and
a source-drain conductive layer above an insulating layer covering the second gate conductive layer, and comprising the source electrode and the drain electrode.

13. The display device of claim 12, wherein the first line and the second line are provided in the source-drain conductive layer.

14. The display device of claim 13, wherein the first connection line and the second connection line are provided in the first gate conductive layer or the second gate conductive layer.

15. The display device of claim 13, wherein the circuit layer further comprises a third gate conductive layer above an insulating layer covering the second gate conductive layer, and
wherein the first connection line and the second connection line are provided in the third gate conductive layer.

16. The display device of claim 1, further comprising a gate-driving circuit in the non-display area on the substrate, and connected to the first line, the second line, and the pixels.

17. The display device of claim 16, wherein the first line and the second line comprise:
a first line portion connected to the electrostatic discharge circuit; and
a second line portion connected to the gate-driving circuit, and spaced apart from the first line portion,
wherein the display device further comprises:
a first bridge line connecting the first line portion and the second line portion of the first line beneath the first line on the substrate; and
a second bridge line connecting the first line portion and the second line portion of the second line beneath the second line on the substrate.

18. The display device of claim 16, wherein the first line is configured to transmit a gate high voltage to the gate-driving circuit, and
wherein the second line is configured to transmit a gate low voltage to the gate-driving circuit.

19. A display device comprising:
pixels in a display area;
data lines connected to the pixels;
an electrostatic discharge circuit at a side of the display area, and connected to the data lines;
a gate-driving circuit at another side of the display area, and connected to the pixels;
a first line for transmitting a first voltage to the gate-driving circuit, and comprising a first line portion connected to the electrostatic discharge circuit, and a second line portion spaced apart from the first line portion and connected to the gate-driving circuit;
a second line for transmitting a second voltage to the gate-driving circuit, and comprising a first line portion connected to the electrostatic discharge circuit, and a second line portion spaced from the first line portion and connected to the gate-driving circuit;
a first bridge line connected between the first line portion and the second line portion of the first line beneath the first line; and
a second bridge line connected between the first line portion and the second line portion of the second line beneath the second line.

20. The display device of claim 19, further comprising:
a first connection line connected between the first line and the electrostatic discharge circuit beneath the first line; and
a second connection line connected between the second line and the electrostatic discharge circuit beneath the second line.
